(19) United States
(12) Patent Application Publication
(10) Pub. No.: US 2025/0357284 A1
(43) Pub. Date: Nov. 20, 2025

(54) ELECTRONIC DEVICES AND METHODS OF MANUFACTURING ELECTRONIC DEVICES

(71) Applicant: Amkor Technology Singapore Holding Pte. Ltd., Valley Point #12-03 (SG)

(72) Inventors: Gi Jeong KIM, Gyeonggi-do (KR); Hyeong Il JEON, Gyeonggi-do (KR); Jin Young KHIM, Seoul (KR)

(73) Assignee: Amkor Technology Singapore Holding Pte. Ltd., Valley Point #12-03 (SG)

(21) Appl. No.: 18/669,032

(22) Filed: May 20, 2024

(51) Int. Cl. H01L 23/495; H01L 23/00; H01L 23/31

(52) U.S. Cl. CPC H01L 23/49562; H01L 23/3107; H01L 23/49575; H01L 24/48; H01L 2224/48175

(57) ABSTRACT

An electronic device includes a substrate comprising a contact including a contact first lateral side and a contact second lateral side. A contact first external terminal extends outward from the contact first lateral side. A contact second external terminal extends outward from the contact first lateral side and is separated from the contact first external terminal by gap. An electronic component is coupled to the contact. An encapsulant covers the substrate and the electronic component. The encapsulant comprises an encapsulant top side, an encapsulant bottom side opposite to the encapsulant top side, and an encapsulant lateral side. The contact first external terminal, the contact second external terminal, are exposed from the encapsulant. A lower side of contact is exposed from the encapsulant top side. The encapsulant covers a portion of the gap proximate to the contact first lateral side. Other examples and related methods are disclosed herein.

### CROSS-REFERENCE TO RELATED APPLICATIONS

Not applicable.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIGS. 1A, 1B, and 1C show a top view, a bottom view, and an X-ray view respectively, of an example electronic device.

FIG. 1D shows a cross-sectional view taken along line 1D-1D in FIG. 1A.

FIG. 1E shows a partial enlarged view of region 1E′ in FIG. 1A.

FIG. 1F shows a partial enlarged view of region 1F′ in FIG. 1A.

FIGS. 2A, 2B, 2C, 2D, and 2E show cross-sectional views of an example method for manufacturing an example electronic device.

FIGS. 3A, 3B, 3C and 3D show an X-ray view, top view, bottom view, and side view, respectively, of an example electronic device.

FIG. 3E shows a cross-sectional view taken along line 3E-3E in FIG. 3A.

FIG. 3F shows an equivalent circuit diagram of the electronic device in FIG. 3A.

FIG. 4 shows an X-ray view of an example electronic device.

FIG. 5A shows a view of an example electronic module assembly with a pair of example electronic devices of FIG. 3A shown in an X-ray view.

FIG. 5B shows a view of an example electronic module assembly with a pair of example electronic devices of FIG. 4 shown in an X-ray view.

FIG. 5C shows an equivalent circuit diagram of the electronic modules in FIGS. 5A and 5B.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. Elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements, and these elements should not be limited by these terms. These terms are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or describe two elements indirectly connected by one or more other elements. For example, if element A is coupled to element B, then element A can be directly contacting element B or indirectly connected to element B by an intervening element C. Similarly, the terms “over” or “on” may be used to describe two elements directly contacting each other or describe two elements indirectly connected by one or more other elements. Unless specified, the term “coupled” can refer to a mechanical coupling or an electrical coupling.

### DESCRIPTION

In some applications, electronic components, such as semiconductor devices, can be encapsulated within a package body where the semiconductor devices can be protected from hostile environments and electrical interconnection between the semiconductor dies and a next level assembly, such as a printed circuit board (PCB) or motherboard, is enabled. Components of an electronic package can generally comprise a conductive substrate such as a metal lead frame, one or more semiconductor devices, a bonding material for attaching the semiconductor devices to the lead frame, interconnects that electrically connect the semiconductor devices to individual leads of the lead frame, and an encapsulant material that covers the semiconductor devices and forms the external shape of an electronic package, commonly referred to as a package body.

In some examples, the metal lead frame can be manufactured by chemically etching or mechanical stamping a metal strip. A portion of the lead frame may be internal to the package body. Portions of the individual leads of the lead frame may extend outward from the package body or may be partially exposed to facilitate electrically coupling the electronic package to other components.

The present description includes, among other features, structures and associated methods that relate to packaged electronic devices including electronic components, such as power components, semiconductor components, and/or passive components. Examples of packaged electronic devices relevant to the present disclosure can include, but are not limited to, a dual-row package, a MicroLead Frame® type package (“MLF”) including a dual-row MLF type package (“DR-MLF”), dual flat no-lead package (“DFN”), small-outline no-lead package (“SON”), quad flat package (“QFP”), quad flat no-lead package (“QFN”), thin substrate chip scale packages (“tsCSP”), and advanced QFN package (“aQFN”). These packaged electronic devices can comprise a conductive substrate, such as metal lead frames with die attach pads, and can either be internal to or exposed from the encapsulant material. In some examples, the packaged electronic devices can comprise conductive materials such as copper (Cu), nickel (Ni), gold (Au), silver (Ag), palladium (Pd), iron (Fe), among other structures in integrated lead frames, and can also comprise insulating materials such as epoxy mold compounds.

The present description is relevant to electronic modules including power modules, which can perform various electrical functions including, but not limited to, power conversion. Such power conversion examples include, but are not limited to, half-bridge converters (e.g., including two switching elements) or full-bridge converters (e.g., including four switching elements). These power converters can comprise a variety of power conversion devices, such as alternating current (AC) to direct current (DC) converters, DC-DC converters, or DC-AC converters, and can convert or regulate power to suit various power requirements depending on the application. Those skilled in the art will understand that although the following description focuses on various lead (Pb)-free lead frame-based structures, the same implementation principles can be applied to lead based lead frame packages.

In some examples, the present description relates to power modules configured to include two or more power semiconductor devices within a small form factor and that use a top exposed contact to promote heat dissipation. In some examples, the contact is configured as a first current carrying terminal for the power module, such as a drain contact, and is provided with a first external terminal and a second external terminal extending from a side of the contact for connecting to a next level of assembly. In some examples, the first external terminal extends in a first direction and the second external terminal extends a second direction. In some examples, the first external terminal and the second external terminal are laterally separated by gap or void configured to reduce height deviation between the first external terminal and the second external terminal, which was found through experimentation to improve bond reliability.

In some examples, a chamfered cutout is provided in the contact between the first and second external terminals, which was found through experimentation to reduce twisting and stress when manufacturing the power module. In some examples, grooves are provided in edges of the first and second external terminals proximate to the contact to improve adhesion between the contact and the package encapsulant. In some examples, the power module comprises second current carrying terminals, such as source terminals, which are provided with partially coined portions configured to improve adhesion between the source terminals and the package encapsulant.

The power modules of the present description are further described in non-limiting power conversion implementations including DC/DC half-bridges for single phase applications to illustrate examples of their design flexibility. Those skilled in the art will appreciate that the power modules of the present description are suitable for other applications as well.

Although the present description describes lead frame type substrates, it is understood that the disclosure also applies to other types of substrates, including, for example, laminate substrates and other substrates known to those skilled in the art. Those skilled in the art will understand that although the following description focuses on various lead (Pb)-free lead frame-based structures, the same implementation principles can be applied to lead based lead frame packages.

In an example, an electronic device includes a substrate comprising a first contact including a first contact top side, a first contact bottom side opposite to the first contact top side, a first contact first lateral side, and a first contact second lateral side opposite to the first contact first lateral side. The substrate includes a first contact first external terminal coupled to and extending outward from the first contact first lateral side and a first contact second external terminal coupled to and extending outward from the first contact first lateral side. The first contact second external terminal and the first contact first external terminal are separated by a gap. The substrate includes a second contact proximate to and laterally separated from the first contact second lateral side. second contact first external terminal coupled to and extending outward from the second contact, and a second contact second external terminal coupled to and extending outward from the second contact. The substrate includes a third contact is proximate to and laterally separated from the first contact second lateral side and a third contact first external terminal coupled to and extending outward from the third contact. A first electronic component includes a first electronic component top side and a first electronic component bottom side opposite to the first electronic component top side. The first electronic component bottom side is coupled to the first contact top side, a first part of the first electronic component top side is electrically coupled to the second contact, and a second part of the first electronic component is electrically coupled to the third contact. An encapsulant covers the substrate and the first electronic component. The encapsulant comprises an encapsulant top side, an encapsulant bottom side opposite to the encapsulant top side, and an encapsulant lateral side. The first contact first external terminal, the first contact second external terminal, the second contact first external terminal, the second contact second external terminal, and the third contact first external terminal are exposed from the encapsulant. The first contact bottom side is exposed from the encapsulant top side. The encapsulant covers a portion of the gap proximate to the first contact first lateral side.

In an example, an electronic device includes a first modular electronic package. The first modular electronic package includes a first current carrying contact comprising a first side, a second side opposite to the first side, a first lateral side, and a second lateral side opposite to the first lateral side; a first external terminal coupled to and extending from the first current carrying contact; a second current carrying contact; a second external terminal coupled to and extending from the second current carrying contact; a first control contact; a first control contact external terminal coupled to and extending from the first control contact; a second control contact; and second control contact external terminal coupled to and extending from the second control contact. The first modular electronic package includes a first electronic component including a first electronic component top side, a first electronic component bottom side opposite to the first electronic component bottom side, wherein the first electronic component bottom side is coupled to the first side of the first current carrying contact, a first part of the first electronic component top side is coupled to the second current carrying contact, and a second part of the first electronic component top side is coupled to the first control contact. The first modular electronic package includes second electronic component including a second electronic component top side and a second electronic component bottom side opposite to the second electronic component top side, wherein the second electronic component bottom side is coupled to the first side of the first current carrying contact, a first part of the second electronic component top side is coupled to the second current carrying contact, and a second part of the second electronic component top side is coupled to the second control contact. The first modular electronic package includes a first encapsulant covers the first substrate, the first electronic component, and the second electronic component. The first encapsulant includes a first encapsulant top side, a first encapsulant bottom side opposite to the first encapsulant top side, a first encapsulant first lateral side, and a first encapsulant second lateral side opposite to the first encapsulant first lateral side. The second side of the first current carrying contact is exposed from the first encapsulant top side. The first external terminal is exposed from the first encapsulant at the first encapsulant first lateral side. The second external terminal, the first control contact external terminal, and the second control contact external terminal are exposed from the first encapsulant at the first encapsulant second lateral side.

In an example, a method of manufacturing an electronic device includes providing a substrate comprising including a first contact comprising a first contact top side, a first contact bottom side opposite to the first contact top side, a first contact first lateral side, and a first contact second lateral side opposite to the first contact first lateral side; a first contact first external terminal coupled to and extending outward from the first contact first lateral side; a first contact second external terminal coupled to and extending outward from the first contact first lateral side, wherein the first contact second external terminal and the first contact first external terminal are separated by a gap; a second contact proximate to and laterally separated from the first contact second lateral side; a second contact first external terminal coupled to and extending outward from the second contact; a second contact second external terminal coupled to and extending outward from the second contact; a third contact proximate to and laterally separated from the first contact second lateral side; and a third contact first external terminal coupled to and extending outward from the third contact. The method includes providing a first electronic component comprising a first electronic component top side and a first electronic component bottom side opposite to the first electronic component top side, wherein the first electronic component bottom side is coupled to the first contact top side, a first part of the first electronic component top side is electrically coupled to the second contact, and a second part of the first electronic component is electrically coupled to the third contact. The method includes providing an encapsulant covering the substrate and the first electronic component. The encapsulant comprises an encapsulant top side, an encapsulant bottom side opposite to the encapsulant top side, and an encapsulant lateral side. The first contact first external terminal, the first contact second external terminal, the second contact first external terminal, the second contact second external terminal, and the third contact first external terminal are exposed from the encapsulant. The first contact bottom side is exposed from the encapsulant top side. The encapsulant covers a portion of the gap proximate to the first contact first lateral side.

Other examples are included in the present disclosure. Such examples may be found in the figures, in the claims, or in the description of the present disclosure.

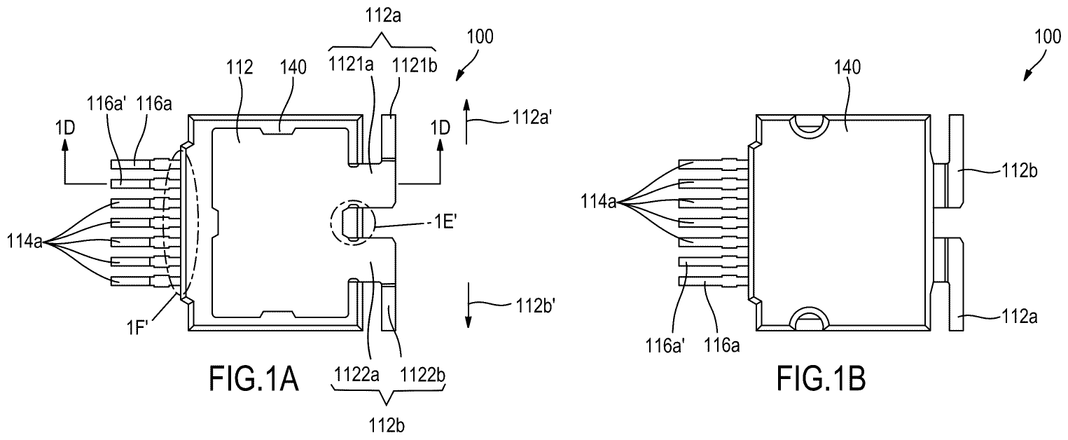

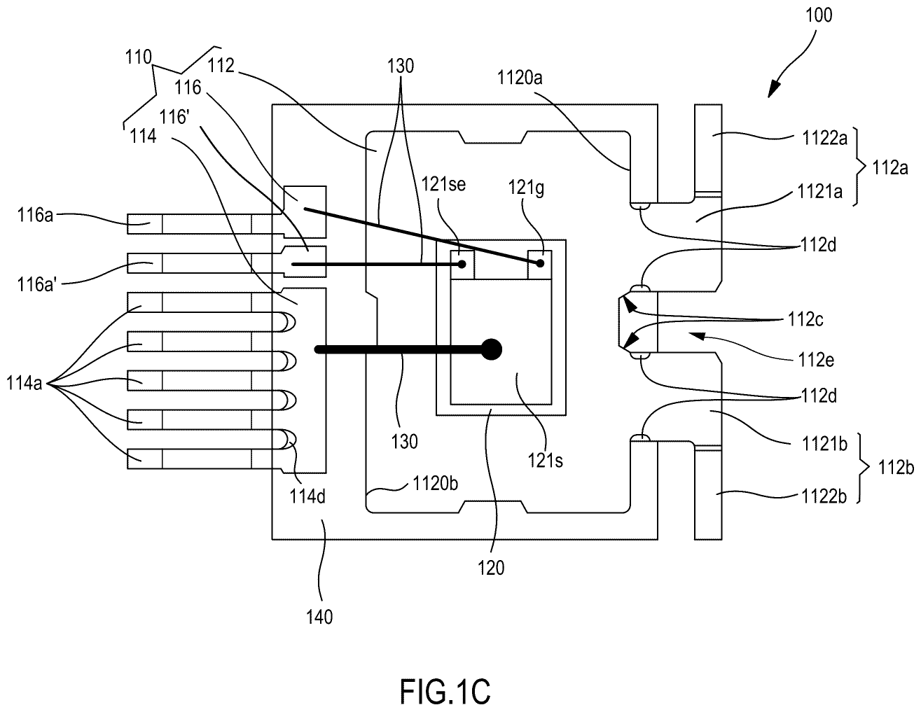

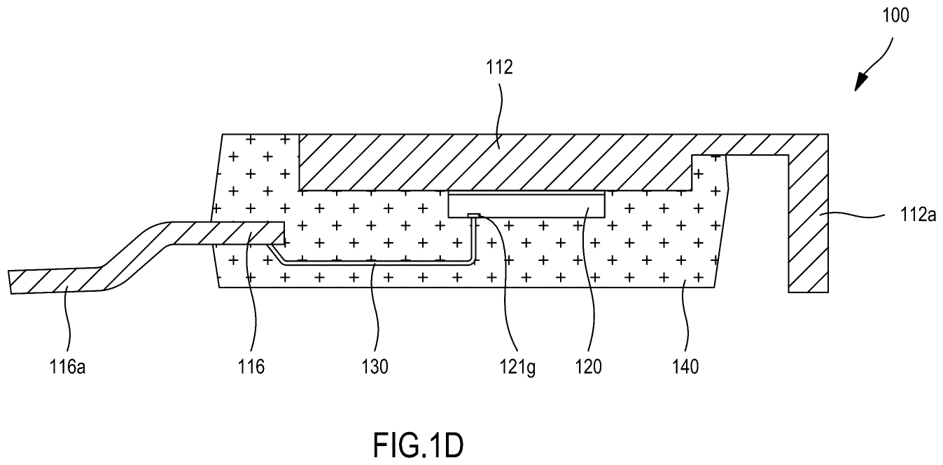

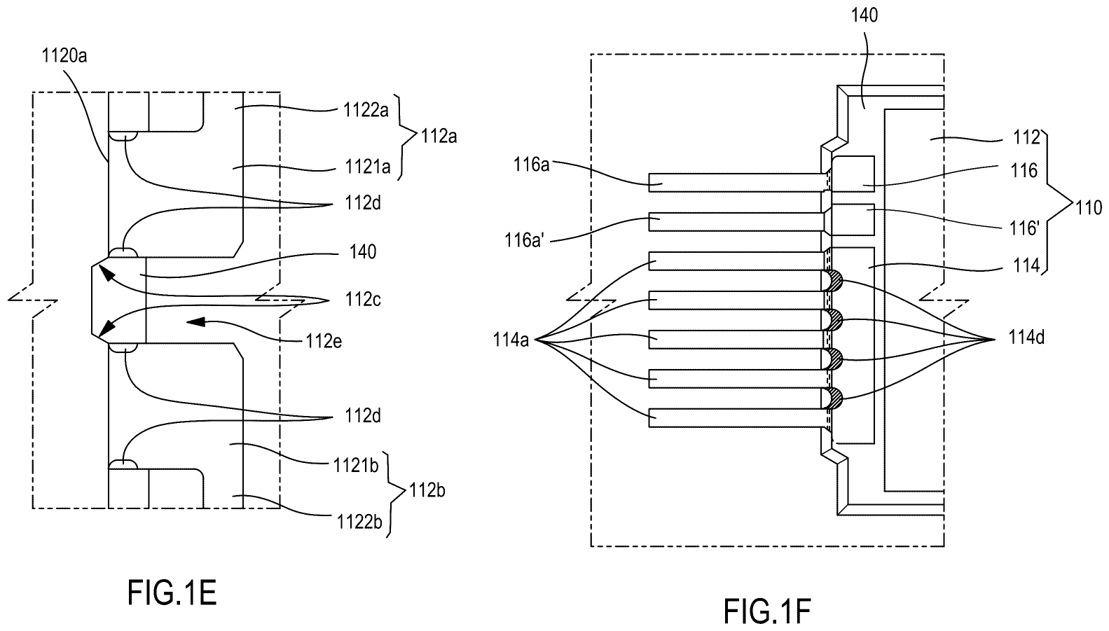

FIGS. 1A and 1B show a top view and bottom view, respectively, of an example electronic device 100. FIG. 1C shows an X-ray view of electronic device 100. FIG. 1D shows a cross-sectional view taken along line 1D-1D in FIG. 1A. In the example shown in FIGS. 1A, 1B, 1C, and 1D, electronic device 100 can comprise substrate 110, electronic component 120, interconnects 130, and encapsulant 140. Electronic device 100 is an example of a power module. In some examples, electronic device 100 can comprise or be referred to as a top exposed pad modular power electronic package.

Substrate 110 can comprise or be referred to as a lead frame or a molded substrate. In accordance with various examples, substrate 110 comprises at least one drain contact 112, at least one source contact 114, and at least one gate contact 116. In some examples, a sensor contact 116′ (shown in FIG. 1C) can be used as an optional sensor or sense terminal, which can be coupled to a small number of transistor cells within electronic component 120 to sense current levels in electronic device 100 for control or monitoring purposes. Drain contact 112 is an example of a first contact or a first current carrying contact and can comprise or be referred to as a drain pad, a drain paddle, a die pad, a die paddle, a heat sink, a heat spreader a conductive pad, a pad, or a current carrying contact. Source contact 114 is an example of a second contact or a second current carrying contact and can comprise or be referred to as a source pad, a source paddle, or a current carrying contact. Gate contact 116 is an example of a third contact or a control contact and comprise or be referred to as a gate pad or a gate paddle. Sensor contact 116′ is an example of a fourth contact and can comprise or be referred to as a sense contact.

In some examples, substrate 110 can comprise a first external drain terminal 112a and a second external drain terminal 112b. First external drain terminal 112a and second external drain terminal 112b extend outward from a side 1120a of drain contact 112 and protrude from or are exposed outside of encapsulant 140. First external drain terminal 112a can also comprise or be referred to as a first lead foot, which extends in a first direction 112a′. Second external drain terminal 112b can also comprise or be referred to as a second lead foot that extends in a second direction 112b′ that is different than first direction 112a′. In some examples, second direction 112b′ is opposite or 180 degrees with respect to first direction 112a′. First external drain terminal 112a is an example of a first external terminal or a first contact first external terminal and second drain terminal 112b is an example of a second external terminal or a first contact second external terminal.

In some examples, substrate 110 can comprise one or more external source terminal(s) 114a that are coupled to and extend outward from source contact 114 and protrude from or are exposed from encapsulant 140. Substrate 110 can comprise one or more external gate terminal(s) 116a that are coupled to and extend outward from gate contact 116 and protrude from or are exposed from encapsulant 140. In some examples, substrate 110 can comprise one or more external sensor terminals 116a′ that are coupled to and extend outward from sensor contact 116′ and protrude from or are exposed from encapsulant 140. External source terminal(s) 114a is an example of a second contact first external terminal or a third external terminal(s), external gate terminal(s) 116a is an example of third contact first external terminal or a fourth external terminal(s), and external sensor terminal(s) 116a′ is an example of a fourth contact first external terminal or a fifth external terminal(s).

In some examples, the thickness of drain contact 112 can be greater than the thickness of source contact 114 and/or gate contact 116. The thicker drain contact 112 tends to allow the current tolerance of an electronic component 120 electrically, thermally, or mechanically coupled to drain contact 112 to be increased or can improve the heat dissipation performance of electronic device 100. In some examples, drain contact 112 can be provided in a generally square or rectangular plate shape. In some examples, the thickness of drain contact 112 can range from approximately 1000 micrometers (μm) to approximately 1400 μm; however, this range is only an example and other thickness can be used. Drain contact 112 can serve as a path through which drain current flows from the drain region of electronic component 120.

In the present example and with reference to FIG. 1C, first external drain terminal 112a comprises a first projection 1121a extending outward from first side 1120a of drain contact 112 and a first extension 1122a extending outward from a side of first projection 1121a in first direction 112a′. First projection 1121a can also comprise or be referred to as a first arm or first tab, and first extension 1122a can also comprise or be referred to as a first lead finger. In some examples, the width of first projection 1121a is wider than the width of first extension 1122a. Second external drain terminal 112b comprises a second projection 1121b extending outward from first side 1120a of drain contact 112 and a second extension 1122b extending outward from a side of second projection 1121b in second direction 112b′. Second projection 1121b can also comprise or be referred to as a second arm or second tab, and second extension 1122b can also comprise or be referred to as a second lead finger. In some examples, the width of second projection 1121b is wider than the width of second extension 1122b. In some examples, the width of first projection 1121a can be the same as or similar to the width of second projection 1121b, and the width of first extension 1122a can be the same as or similar to the width of second extension 1122b.

In accordance with the present description and further with reference to FIG. 1C, first projection 1121a and second projection 1121b are separated from each by a gap 112e. Gap 112e can also comprise or be referred to as a slot, pocket, or cut-out. In accordance with the present description, gap 112e is defined by an inward side of first projection 1121a, an inward side of second projection 1121b, and a portion of first side 1120a of drain contact 112.

In some examples, first extension 1112a of first external drain terminal 112a and second extension 1112b of second external drain terminal 112b are formed or bent such that they extend in a direction toward the bottom side of encapsulant 140 (for example, toward the side of encapsulant 140 that faces away from drain contact 112). In some examples, the thicknesses of first external drain terminal 112a and second external drain terminal 112b can range from approximately 200 μm to approximately 800 μm; however, this range is only an example and other ranges can be used. First external drain terminal 112a and second external drain terminal 112b can be coupled to a next level of assembly, such as an external circuit board, thereby providing a drain current flow path between electronic device 100 and the next level of assembly.

In some examples, source contact 114 can be spaced apart from drain contact 112. For example, source contact 114 can be spaced apart from side 1120b (see FIG. 1C) of drain contact 112, which is opposite to first side 1120a of drain contact 112. In some examples, source contact 114 can have a generally rectangular plate shape. In some examples, the thickness of source contact 114 can be smaller than the thickness of drain contact 112. The thickness of source contact 114 can range from approximately 200 μm to approximately 800 μm; however, this range is only an example and other ranges can be used. Source contact 114 can serve as a path through which source current flows to and from the source region of electronic component 120.

In some examples, external source terminal 114a can comprise a plurality of external source terminals 114a coupled to and extending outward from source contact 114. In some examples, each external source terminals 114a can extend in a generally vertical direction to one side of drain contact 112 and can also extend in a generally vertical direction to one side of encapsulant 140. In some examples, external source terminals 114a are formed or bent in a direction toward the bottom side of encapsulant 140. The bent structure can aid in coupling external source terminals 114a to a next level of assembly, such as an external circuit board. In some examples, the thickness of external source terminal 114a can range from approximately 200 μm to approximately 800 μm; however, this range is only an example and other ranges can be used. External source terminal 114a can be coupled to the next level of assembly to provide a source current flow path between electronic device 100 and the next level of assembly. In other examples, external source terminals 114a can be disposed adjacent to other sides of drain contact 112.

In some examples, gate contact 116 can be spaced apart from second side 1120b of drain contact 112, which is opposite to first side 1120a of drain contact 112 and opposite to first and second external drain terminals 112a and 112b. In some examples, at least one gate contact 116 can be provided. In some examples, the thickness of gate contact 116 can be smaller than the thickness of drain contact 112. In some examples, gate contact 116 can be provided in a generally square plate shape. In some examples, the thickness of gate contact 116 can range from approximately 200 μm to approximately 800 μm; however, this range is only an example and other ranges can be used. Gate contact 116 can serve as a passage through where a control signal, such as a gate voltage can be applied to the gate region of electronic component 120.

In some examples, external gate terminal 116a is coupled to and can extend outward from gate contact 116. In some examples, external gate terminal 116a can extend in a direction generally perpendicular to second side 1120b of drain contact 112 and can also extend in a direction generally perpendicular to one side of encapsulant 140. In some examples, external gate terminal 116a can be coupled to a next level of assembly, such as an external circuit board by being formed or bent in a direction toward the bottom side of encapsulant 140. In some examples, the thickness of external gate terminal 116a can range from approximately 200 μm to approximately 800 μm; however, this range is only an example and other ranges can be used. External gate terminal 116a can be mounted on the next level of assembly to provide a gate voltage application path between electronic device 100 and the next level of assembly.

In some examples, external sensor terminal 116a′ is coupled to and can extend outward from sensor contact 116′. In some examples, external sensor terminal 116a′ can extend in a direction generally perpendicular to second side 1120b of drain contact 112 and can also extend in a direction generally perpendicular to one side of encapsulant 140. In some examples, external sensor terminal 116a′ can be coupled to a next level of assembly, such as an external circuit board by being formed or bent in a direction toward the bottom side of encapsulant 140. In some examples, the thickness of external sensor terminal 116a′ can range from approximately 200 μm to approximately 800 μm; however, this range is only an example and other ranges can be used. External sensor terminal 116a′ can be mounted on the next level of assembly to provide a sense path between electronic device 100 and the next level of assembly.

Electronic component 120 can comprises a semiconductor material and can be coupled to drain contact 112. In some examples, electronic component 120 can comprise a drain region provided on the lower side of the semiconductor material and electrically coupled to drain contact 112, a source region provided on the upper side of the semiconductor material and electrically coupled to source contact 114, a gate region provided on the upper side electrically coupled to gate contact 116, and a sense region can be provided on the upper side and electrically coupled to sensor contact 116′. In some examples, the source region, the gate region, and the sense region can each comprise source bond pad 121s, gate bond pad 121g, and sensor bond pad 121se respectively. In some examples, the drain region of electronic component 120 can be electrically coupled to drain contact 112 with a conductive adhesive. In some examples, source bond pad 121s of electronic component 120 can be electrically coupled to source contact 114 through an interconnect 130. In some examples, gate bond pad 121g of electronic component 120 can be electrically coupled to gate contact 116 with another interconnect 130. In some examples, sensor bond pad 121se of electronic component 120 can be electrically coupled to sensor contact 116′ with a further interconnect 130. In some examples, interconnects 130 can comprise wire bonds (for example, gold, copper, or aluminum wires), clips (for example copper, copper alloy, or aluminum), ribbon bonds (for example, copper or copper alloy), other interconnect structures as known to one of ordinary skill in the art, or combinations thereof. It is understood that different types of interconnects can be used for the different electrical interconnects. Such differences can include structural or type, size, or material. In some examples, the diameter or thickness of interconnect 130 can range from approximately 50 μm to approximately 500 μm and can depend on power requirements.

Electronic component 120 can comprise or be referred to as a die, a chip, a package, or a passive element. In some examples, electronic component 120 can comprise a metal-oxide-semiconductor field-effect transistor (MOSFET), an insulated-gate bipolar transistor (IGBT), a thyristor, or a bipolar junction transistor (BJT). The thickness of electronic component 120 can range from approximately 50 μm to approximately 400 μm. In some examples, electronic component 120 functions as a switching device, which can conduct current or block current depending on the gate voltage applied to the gate region and can be used with other electronic devices to provide, for example, a power conversion structure.

In some examples and with reference to FIGS. 1A, 1C, and 1D, encapsulant 140 can encapsulate, cover, or surround substrate 110, electronic component 120, and interconnect 130. Encapsulant 140 can surround at least portions of drain contact 112, source contact 114, sensor contact 116′, and gate contact 116. In some examples, external drain terminal(s) 112a, 112b, external source terminal(s) 114a, external sensor terminal 116a′, and external gate terminal 116a can each protrude or extend outwardly and are exposed from encapsulant 140. In some examples, some areas of drain contact 112 may be exposed from encapsulant 140. In some examples and as shown in FIGS. 1A and 1D, the opposite side of drain contact 112 to where electronic component 120 is coupled can be exposed from encapsulant 140. In some examples, the exposed surface of drain contact 112 can be substantially coplanar with a side or major surface of encapsulant 140. Encapsulant 140 can comprise or be referred to as an epoxy molding compound, resin, filler-reinforced polymer. a B-stage compressed film or gel. The thickness of encapsulant 140 can range from approximately 2.5 millimeter (mm) to approximately 4.5 mm. Encapsulant 140 can isolate, insulate, and protect substrate 110, electronic component 120, and interconnect 130 from external hostile environments. Electronic device 100 is an example of a drain-up electronic device or a source down electronic device where drain contact 112 is provided adjacent to a top side of encapsulant 140 and source contact 114, sensor contact 116′, and gate contact 116 are provided adjacent to a bottom side of encapsulant 140.

FIG. 1E is an enlarged partial view of region 1E′ of FIG. 1A showing a portion drain contact 112. With reference to FIG. 1C and FIG. 1E, in some examples grooves 112d can be provided in some regions of external drain terminals 112a and 112b. In some examples, grooves 112d extend partially into drain terminals 112a and 112b. In some examples, grooves 112d can be provided in opposing sides of first projection 1121a and opposing sides of second projection 1121b. In some examples, grooves 112d can be provided in regions of first projection 1121a and second projections 1121b proximate to first side 1120a of drain contact 112. Grooves 112d can each comprise or be referred to as a recess, unevenness, thinned portions, or an embossed region. In some examples, grooves 112d can be provided by chemical etching, mechanical compression stamping, mechanical compression coining, or combinations thereof. In some examples, grooves 112d can be covered by encapsulant 140. In some examples, the depths of grooves 112d can range from approximately 150 μm to approximately 400 μm. In some examples, the depths of grooves 112d can range from approximately 15% to approximately 75% of the thickness of first and second external drain terminals 112a and 112b. In some examples, the depths of grooves 112d can range from approximately 25% to approximately 50% of the thickness of first and second external drain terminals 112a and 112b. In some examples, the depths of grooves 112d can range from approximately 50% to approximately 75% of the thickness of first and second external drain terminals 112a and 112b. Grooves 112d can improve the bonding force between external drain terminals 112a and 112b and encapsulant 140 and can also reduce delamination between external drain terminals 112a and 112b from encapsulant 140.

In some examples, chamfers 112c can be provided in portions of drain contact 112. In some examples, chamfers 112c can be provided by removing portions of drain contact 112 proximate to first side 1120a where external drain terminals 112a and 112b start and proximate to gap 112e. In some examples, chamfers 112c can be provided by removing some portions of the area of drain contact 112 closest to first projection 1121a of external drain terminal 112a and second projection 1121b of external drain terminal 112b. In some examples, encapsulant 140 can be coupled to chamfers 112c. In some examples, encapsulant 140 fills a portion of gap 112e and contacts lateral edges of chamfers 112c. Chamfers 112c are angled with respect to first side 1120a of drain contact 112 and the angle is less than 90 degrees. In some examples, the angle is between 30 degrees and 60 degrees. In some examples, the angle is 45 degrees. In some examples, Chamfers 112c can comprise or be referred to as angled sides, recesses, or cutouts. In some examples, chamfers 112c can be provided by chemical etching or mechanical compression stamping.

In some examples, the depths of chamfers 112c recessed inward from first side 1120a of drain contact 112 can range from approximately 200 μm to approximately 800 μm. Chamfers 112c can improve the flatness of drain contact 112 or external drain terminals 112a and 112b. In some examples, when external drain terminals 112a and 112b are separated from a frame body (e.g., by singulation or sawing), stress can be applied to external drain terminals 112a and 112b or drain contact 112. As a result, external drain terminals 112a and 112b or drain contact 112 can be deformed or twisted. It was found through experimentation that chamfers 112c reduce such effects. More particularly chamfers 112c help to maintain the flatness of external drain terminals 112a and 112b and drain contact 112. This improves manufacturing yields and device quality and reliability.

FIG. 1F shows a partial enlarged view taken along region 1F′ in FIG. 1A and shows a portion of source contact 114. In the example shown in FIG. 1F, grooves 114d can be provided in some regions of source contact 114. In some examples, grooves 114d can be provided at ends of external source terminals 114a proximate to source contact 114. In some examples, grooves 114d can be provided in portions of source contact 114 located between adjacent external source terminals 114a. In some examples, grooves 114d extend partially into source contact 114. In some examples, grooves 114d can be covered with encapsulant 140. Grooves 114d can each comprise or be referred to as an unevenness, recess, thinned portion, or an embossed region. In some examples, grooves 114d can be provided by chemical etching, mechanical compression stamping, mechanical compression coining, or combinations thereof. The depths of grooves 114d can range from approximately 150 μm to approximately 400 μm. In some examples, the depths of grooves 114d can range from approximately 15% to approximately 75% of the thickness of source contact 114. In some examples, the depths of grooves 114d can range from approximately 25% to approximately 50% of the thickness of source contact 114. In some examples, the depths of grooves 114d can range from approximately 50% to approximately 75% of the thickness of source contact 114. Grooves 114d can improve the bonding force between source contact 114 and encapsulant 140 and can also reduce delamination of source contact 114 from encapsulant 140.

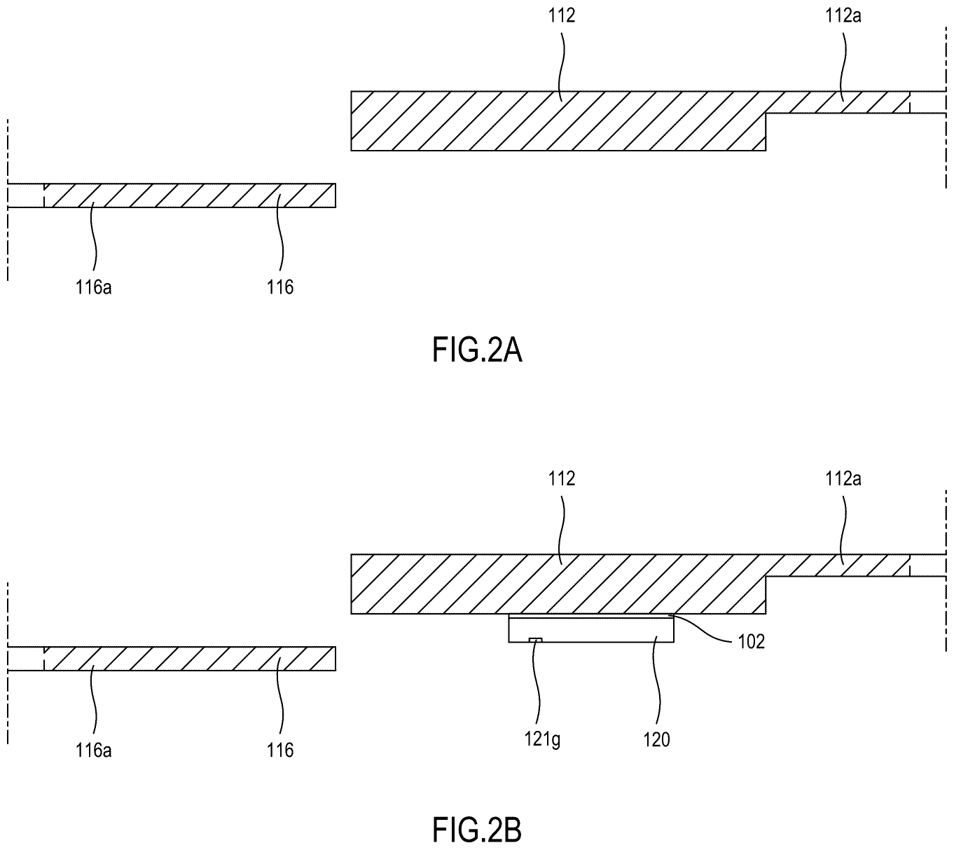

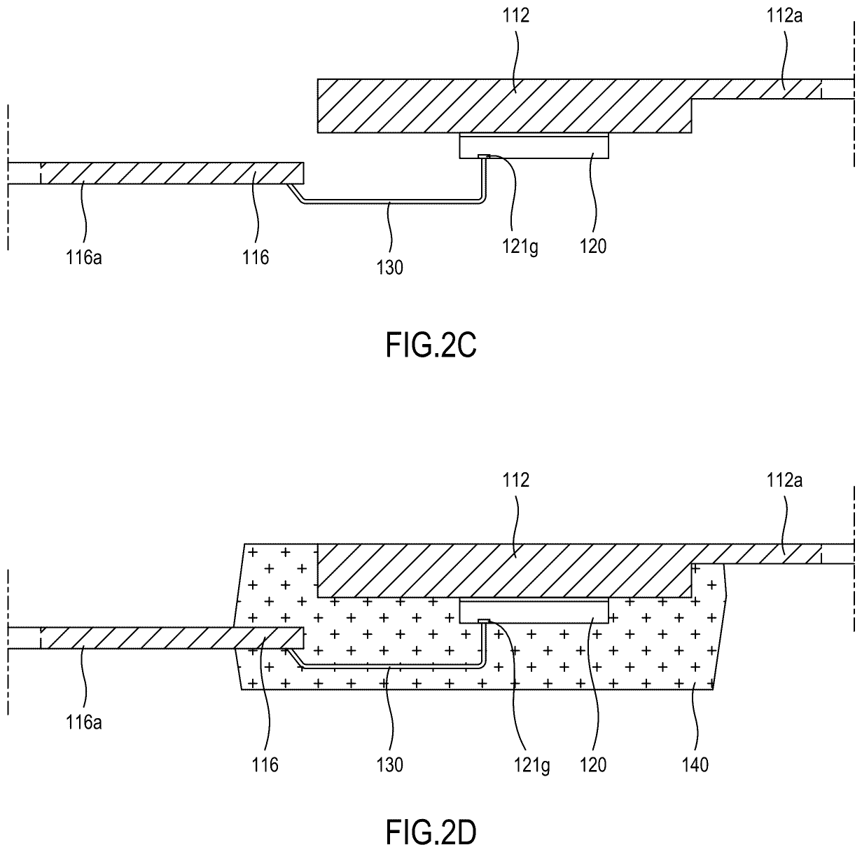

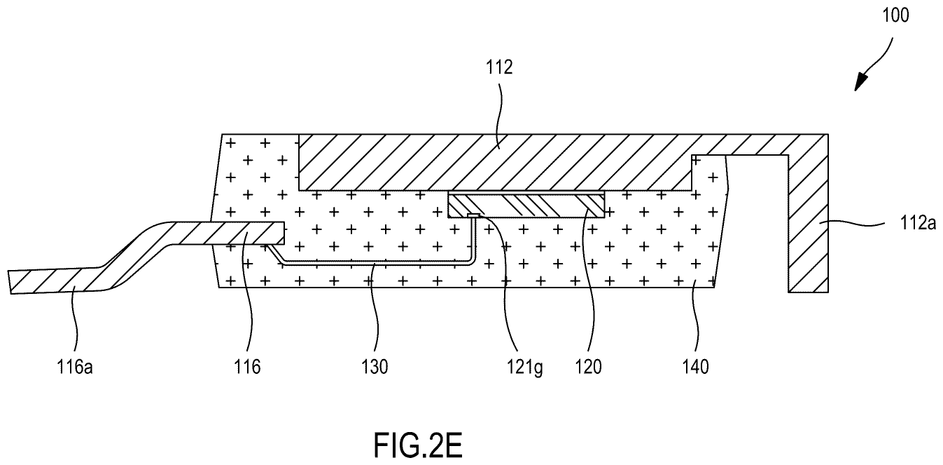

FIGS. 2A, 2B, 2C, 2D, and 2E show cross-sectional views of an example method for manufacturing an example electronic device, such as electronic device 100. Here, similar features described previously with electronic device 100 may not be repeated, and reference to some elements may not be shown in FIGS. 2A-2E but are shown in FIGS. 1A to 1F.

FIG. 2A shows a cross-sectional view of electronic device 100 at an early stage of manufacture. In the example shown in FIG. 2A, substrate 110 can be provided. Substrate 110 can comprise drain contact 112, source contact 114, sensor contact 116′, and gate contact 116. In some examples, substrate 110 can comprise external drain terminal 112a and external drain terminal 112b extending from drain contact 112, at least one external source terminal 114a extending from source contact 114, at least external sensor terminal 116a′ extending from sensor contact 116′, and at least one external gate terminal 116a extending from gate contact 116. In some examples, drain contact 112 can be connected to a frame body with a tie bar(s) to provide drain contact 112 with support during manufacturing.

In some examples, external drain terminals 112a and 112b can be connected to and supported by the frame body through a dam bar provided across external drain terminals 112a and 112b. In some examples, external source terminal 114a, external sensor terminal 116a′, or external gate terminal 116a can be connected to and supported by the frame body through another dam bar provided across external source terminal 114a, external sensor terminal 116a′, or external gate terminal 116a. In some examples, external drain terminals 112a and 112b, external source terminal 114a, external sensor terminal 116a′, or external gate terminal 116a can be supported by having their distal ends connected to the frame body. In some examples, the thickness of drain contact 112, the thickness of source contact 114, the thickness of sensor contact 116′, and the thickness gate contact 116 can be different. In some examples, the thickness of drain contact 112 can be relatively greater than the thicknesses of source contact 114, sensor contact 116′, and gate contact 116. In the present example, drain contact 112 lies within or resides on a first plane and gate contact 116, sensor contact 116′, and source contact 114 lie within or reside on a second plane that is different than or offset with respect to the first plane. In some examples, the first plane is elevated above the second plane in a cross-sectional view.

FIG. 2B shows a cross-sectional view of electronic device 100 at a later stage of manufacture. In the example shown in FIG. 2B, electronic component 120 can be provided. In some examples, the drain region of electronic component 120 can be electrically connected to drain contact 112 using an attachment structure, such as a conductive adhesive 102. In some examples, one or more conductive materials, such as Sn, Ag, Pb, Cu, Sn—Pb, Sn37-Pb, Sn95-Pb, Sn—Pb—Ag, Sn—Cu, Sn—Ag, Sn—Au, Sn—Bi, or Sn—Ag—Cu can be provided on drain contact 112 or the drain region of electronic component 120. Thereafter, electronic component 120 can be placed on drain contact 112 using conductive adhesive 102, and a reflow process or a thermal compression process can then be performed so that electronic component 120 is coupled to drain contact 112.

FIG. 2C shows a cross-sectional view of electronic device 100 at a later stage of manufacture. In the example shown in FIG. 2C, interconnect 130 can be provided. Electronic component 120 and substrate 110 can be electrically coupled through interconnect 130, such as a conductive wire, ribbon bond, or a conductive clip. In some examples, interconnect 130 can electrically couple gate bond pad 121g of electronic component 120 to gate contact 116 by a wire bonding process. In some examples, one end of interconnect 130 can be ball-bonded to gate bond pad 121g, and the other end of interconnect 130 can be stitch-bonded to gate contact 116. In some examples, another interconnect 130 can electrically connect source bond pad 121s of electronic component 120 to source contact 114 (see FIG. 1C) by a wire bonding process. In some examples, one end of interconnect 130 can be ball-bonded to source bond pad 121s, and the other end of interconnect 130 can be stitch-bonded to source contact 114. In some examples, another interconnect 130 can electrically connect sensor bond pad 121se of electronic component 120 to sensor contact 116′ (see FIG. 1C) by a wire bonding process. In some examples, one end of interconnect 130 can be ball-bonded to sensor bond pad 121se, and the other end of interconnect 130 can be stitch-bonded to sensor contact 116. In this way, the drain region of electronic component 120 can be electrically coupled to drain contact 112 and external drain terminal 112a and external drain terminal 112b, the source region of electronic component 120 can be electrically coupled to source contact 114 and external source terminal 114a, the sensor region of electronic component 120 can be electrically coupled to sensor contact 116′ and external sensor terminal 116a′, and the gate region of electronic component 120 can be electrically coupled to gate contact 116 and external gate terminal 116a.

FIG. 2D shows a cross-sectional view of electronic device 100 at a later stage of manufacture. In the example shown in FIG. 2D, encapsulant 140 can be provided. In some examples, encapsulant 140 can be provided by compression molding, transfer molding, liquid encapsulant molding, vacuum lamination, paste printing, or film assisted molding. Compression molding can be a process of supplying a fluid resin to a mold in advance and then curing the fluid resin by putting substrate 110 described above into the mold, and transfer molding can be a process of supplying a resin to the surrounding area of substrate 110 by using a gate (supply port). After this process, hardened encapsulant 140 can be ejected from the mold. Substrate 110, electronic component 120, and interconnect 130 can be encapsulated, covered, or surrounded by encapsulant 140. In substrate 110, external drain terminals 112a and 112b, external source terminals 114a, external sensor terminal 116a′, and external gate terminal 116a can protrude outward and exposed from encapsulant 140. In some examples, one side of drain contact 112 can be exposed from one side of encapsulant 140.

In some examples, after the encapsulation process, a plating process can be performed. Solder, nickel, palladium, or gold can be plated on the exposed surfaces of external drain terminals 112a, 112b, external source terminals 114a, external sensor terminal 116′a, or external gate terminal 116a. Accordingly, corrosion of the terminals can be prevented, and solder mixing properties can also be improved when electronic device 100 is mounted on an external circuit board. In some examples, when a lead frame substrate with PPF (Pre-Plated Frame) technology is used, the plating process described above can be omitted.

FIG. 2E shows a cross-sectional view of electronic device 100 at a later stage of manufacture. In the example shown in FIG. 2E, a trimming-and-forming process can be performed. In some examples, substrate 110 can be placed in a trimming-and-forming device to trim and form various features of substrate 110. In some examples, ends of external drain terminals 112a and 112b connected to the frame body, ends of external source terminal 114a, the end of external sensor terminal 116a′, or the end of external gate terminal 116a can be cut, and a dam bar connecting the terminals to each other can be cut to be removed. In some examples, external drain terminals 112a and 112b, external source terminal 114a, external sensor terminal 116a′, or external gate terminal 116a can be bent into a predetermined shape to facilitate mounting to an external circuit board.

In some examples, after the trimming-and-forming process, a punching process can be performed. In some examples, after substrate 110 is placed within a punching device, at least one tie bar connecting electronic device 100 and the frame body can be removed so that electronic device 100 is separated from the frame body. Although the manufacturing process of one electronic device 100 has been described, it is understood that multiple electronic devices 100 can be manufactured from one frame body.

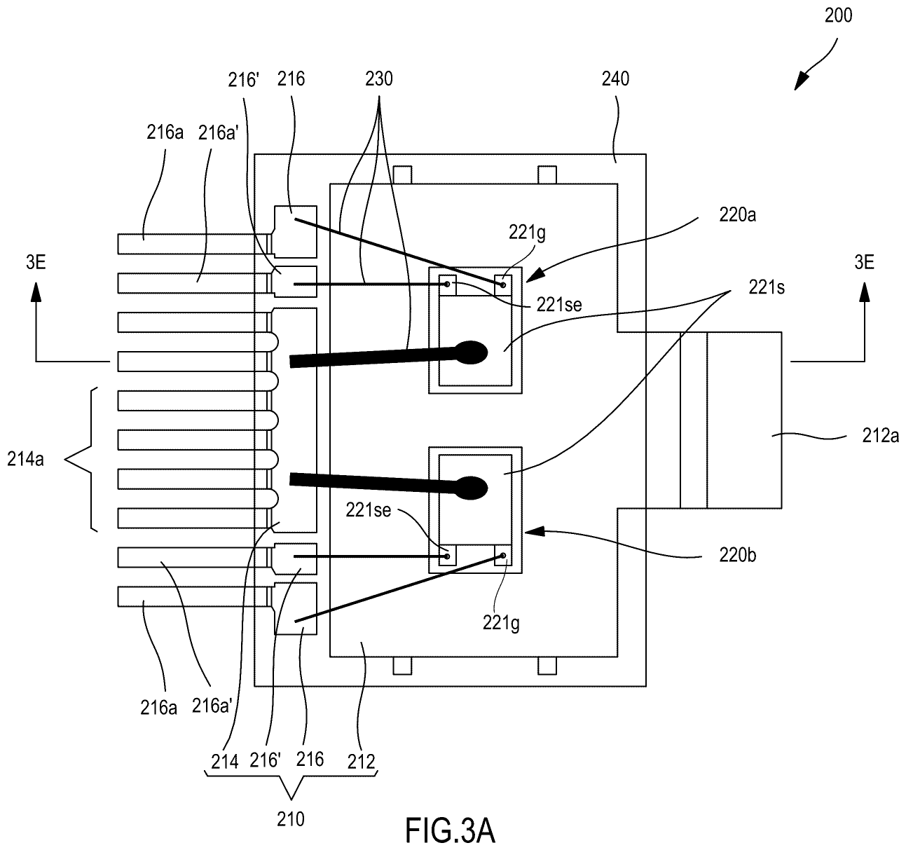

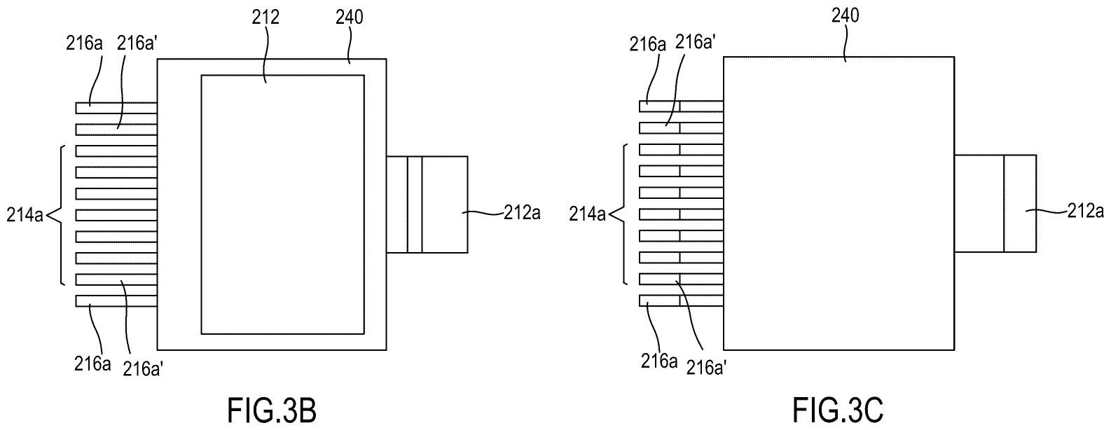

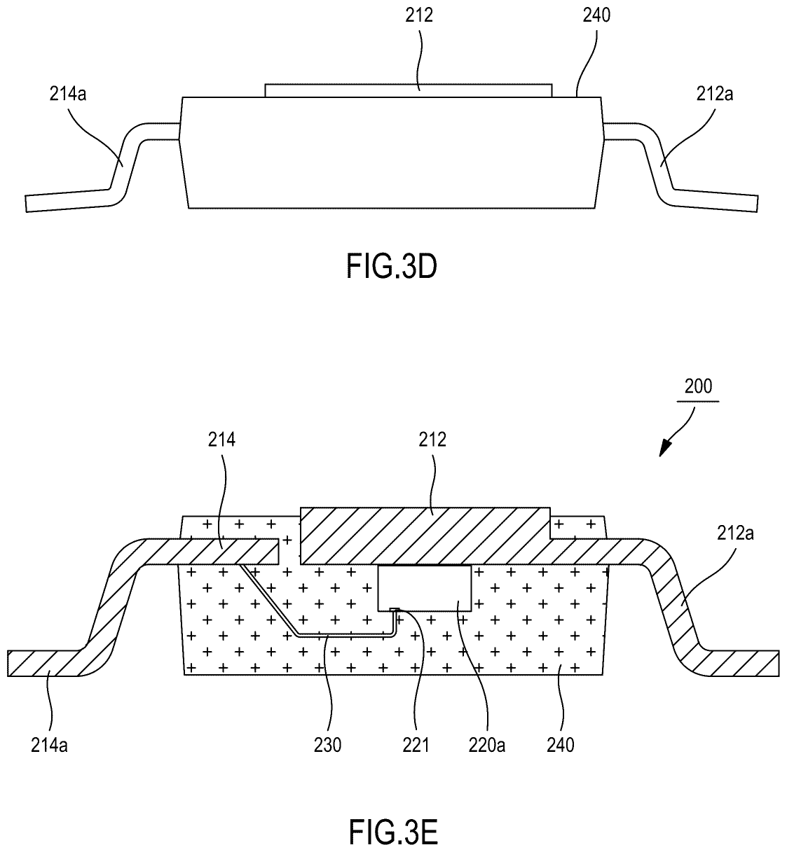

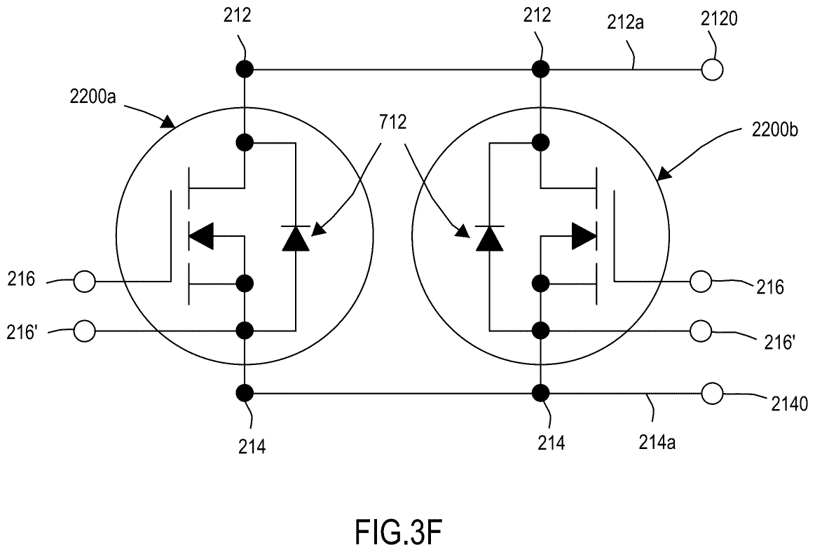

FIGS. 3A, 3B, 3C and 3D show an X-ray view, top view, bottom view, and side view of an example electronic device 200, respectively, and FIG. 3E shows a cross-sectional view taken along line 3E-3E in FIG. 3A. In the example shown in FIGS. 3A, 3B, 3C, 3D and 3E, electronic device 200 can comprise substrate 210, electronic components 220a and 220b, interconnects 230, and encapsulant 240. Electronic device 200 can be similar to electronic device 100 shown in FIGS. 1A, 1B, and 1C, and thus the following description will focus mainly on the differences between electronic device 200 and electronic device 100. Electronic device 200 is an example of a power module configured to include two or more power semiconductor devices within a small form factor and that uses a top exposed contact (e.g., a top exposed drain contact) to promote heat dissipation. In some examples, electronic device 200 can comprise or be referred to as a top exposed pad modular power electronic package. Electronic device 200 is an example of a modular electronic package and a pair of electronic devices 200 can comprise or be referred to as a first modular electronic package and a second modular electronic package.

Substrate 210 can comprise drain contact 212, source contact 214, and gate contact 216. In some examples, substrate 210 can also comprise at least one sensor contact 216′. In other examples, sensor contact 216′ can be excluded. In some examples, the shape of sensor contact 216′ can be similar to the shape of gate contact 216. In some examples, substrate 210 can comprise at least one external drain terminal 212a that is coupled to and extends from drain contact 212 and protrudes and is exposed from encapsulant 240. In some examples, substrate 210 can comprise at least one external source terminal 214a that is coupled to and extends from source contact 214 and protrudes and is exposed from encapsulant 240. In some examples, substrate 210 can comprise at least one external gate terminal 216a that is coupled to and extends from gate contact 216 and protrudes and is exposed from encapsulant 240. In some examples, substrate 210 can comprise at least one external sensor terminal 216a′ that is coupled to and extends from the sensor contact 216′ and protrudes and is exposed from encapsulant 240. In some examples, the shape of external sensor terminal 216a′ can be similar to the shape of external gate terminal 216a.

Drain contact 212 is an example of a first contact or a first current carrying contact and can comprise or be referred to as a drain pad, a drain paddle, a die pad, a die paddle, a heat sink, a heat spreader a conductive pad, a pad, or a current carrying contact. Source contact 214 is an example of a second contact or a second current carrying contact and can comprise or be referred to as a source pad, a source paddle, or a current carrying contact. Gate contacts 216 are examples of third contacts or control contacts and can comprise or be referred to as gate pads or gate paddles. Sensor contacts 216′ are examples of fourth contacts and can comprise or be referred to as sense contacts.

In some examples, drain contact 212 can be provided in the shape of a generally square plate, and external drain terminal 212a can extend in the horizontal direction from one side of the square plate and can be bent in a downward direction from drain contact 212 (see, for example, FIGS. 3D and 3E). In other examples, electronic device 200 can comprise drain contact 112 with external drain terminals 112a and 112b separated by gap 112e as well as one or more of chamfers 112c, grooves 112d, or grooves 114d as described previously with FIGS. 1A to 1F.

In some examples, source contact 214 can be spaced apart from one side of drain contact 212. In some examples, external source terminals 214a can extend laterally outward from source contact 214 and bent in a downward direction from source contact 214 (see, for example, FIGS. 3D and 3E). In some examples, gate contacts 216 can be laterally spaced apart on opposing sides of source contact 214. In some examples, gate contacts 216 can each comprise an external gate terminal 216a extending laterally outward from gate contact 216 and bent in a downward direction from gate contacts 216.

In some examples, sensor contacts 216′ can be laterally spaced apart on opposing sides of source contact 214. In some examples, the sensor contacts 216′ can have an external sensor terminal 216a′ extending laterally outward from sensor contacts 216′ and bent a downward direction from sensor contacts 216′. In some examples, sensor contacts 216′ can be located between source contact 214 and gate contacts 216. In some examples, the sensor contacts 216′ can be located outside gate contacts 216. In some examples, external drain terminal 212a can be placed on one side of drain contact 212, and external source terminal 214a, external gate terminals 216a, or external sensor terminals 116a′ can be placed in a location or side opposite to external drain terminal 212a. It is understood that external source terminal 214a, external gate terminals 216a, or external sensor terminals 116a′ can be placed in other locations.

In some examples, the drain region of first electronic components 220a and the drain region of second electronic component 220b can be coupled to drain contact 212. First electronic component 220a and second electronic component 220b can be spaced apart from each other. First electronic component 220a and second electronic component 220b can each comprise a source region coupled to source contact 214, a gate region coupled to gate contact 216, and a sensor region coupled to sensor contact 216′, respectively. In some examples, the source regions can include a source bond pad 221s, the gate regions can include a gate bond pad 221g, and the sensor regions can include a sensor bond pad 221se. In some examples, source bond pad 221s can be larger than the gate bond pad 221g or sensor bond pad 221se because a greater or larger current flows through source bond pad 221s compared to the gate bond pad 221g or sensor bond pad 221se.

Interconnects 230 can electrically connect source bond pads 221s provided in first electronic component 220a and second electronic component 220b to source contact 214. Interconnects 230 can electrically connect gate bond pads 221g provided in first electronic component 220a and second electronic component 220b to gate contacts 216. Interconnects 230 can electrically connect sensor bond pads 221se provided in first electronic component 220a and second electronic component 220b to sensor contacts 216′. In some examples, because of the higher current flow, the diameter or thickness of source interconnect 230 can be larger than the diameter or thickness of gate interconnect 230 or sensor interconnect 230.

Encapsulant 240 can surround, cover, or encapsulate substrate 210, first electronic component 220a, second electronic component 220b, and interconnects 230. Encapsulant 240 can surround drain contact 212, source contact 214, gate contacts 216, and sensor contacts 216′ of substrate 210. In some examples, external drain terminal 212a, external source terminal 214a, external gate terminals 216a, and external sensor terminals 216a′ can each protrude from or be exposed from encapsulant 240.

FIG. 3F shows an equivalent switching circuit diagram for electronic device 200 of FIGS. 3A, 3B, and 3C. In some examples, the switching circuit can comprise first and second (N-channel) MOSFETs 2200a and 2200b connected in parallel with each other. In some examples, the switching circuit can comprise P-channel MOSFETs or IGBTs connected in parallel with each other.

In some examples, the drain region of first electronic component 220a and the drain region of second electronic component 220b are coupled to common drain contact 212 in electronic device 200, and in the equivalent switching circuit of FIG. 3F, the drain region (denoted as drain contact 212) of first MOSFET 2200a and the drain region (denoted as drain contact 212) of second MOSFET 2200b are coupled through external drain terminal 212a to provide a common drain node 2120. In some examples, the source region of first electronic component 220a and the source region of second electronic component 220b are coupled to common source contact 214 in electronic device 200, and in the equivalent switching circuit, the source region (denoted as source contact 214) of first MOSFET 2200a and the source region (denoted as source contact 214) of second MOSFET 2200b are coupled through external source terminal(s) 214a to provide a common source node 2140.

In some examples, the gate region of first electronic component 220a and the gate region of second electronic component 220b are each electrically connected to separate gate contacts 216, and in the equivalent switching circuit of FIG. 3F, the gate (denoted as gate contact 216) of first MOSFET 2200a and the gate region (denoted as gate contact 216) of second MOSFET 2200b are separated from each other and can be separately biased or commonly biased at a board level, using for example, a control integrated circuit (IC). In some examples, the sensor region of first electronic component 220a and the sensor region of second electronic component 220b are each electrically connected to separate sensor contacts 216′, and in the equivalent switching circuit of FIG. 3F, the sensor region (denoted as sensor contact 216′) of first MOSFET 2200a and the sensor region (denoted as sensor contact 216′) of second MOSFET 2200b are separated from each other and can be separately monitored or commonly monitored at a board level using for example, a separate control IC.

In some examples, first MOSFET 2200a and second MOSFET 2200b can each comprise a body diode (or a parasitic diode) 712 having a reverse blocking direction from drain to source. In some examples, the switching circuit shown in FIG. 3F can be used as a high side switch or a low side switch for a single-phase half-bridge converter.

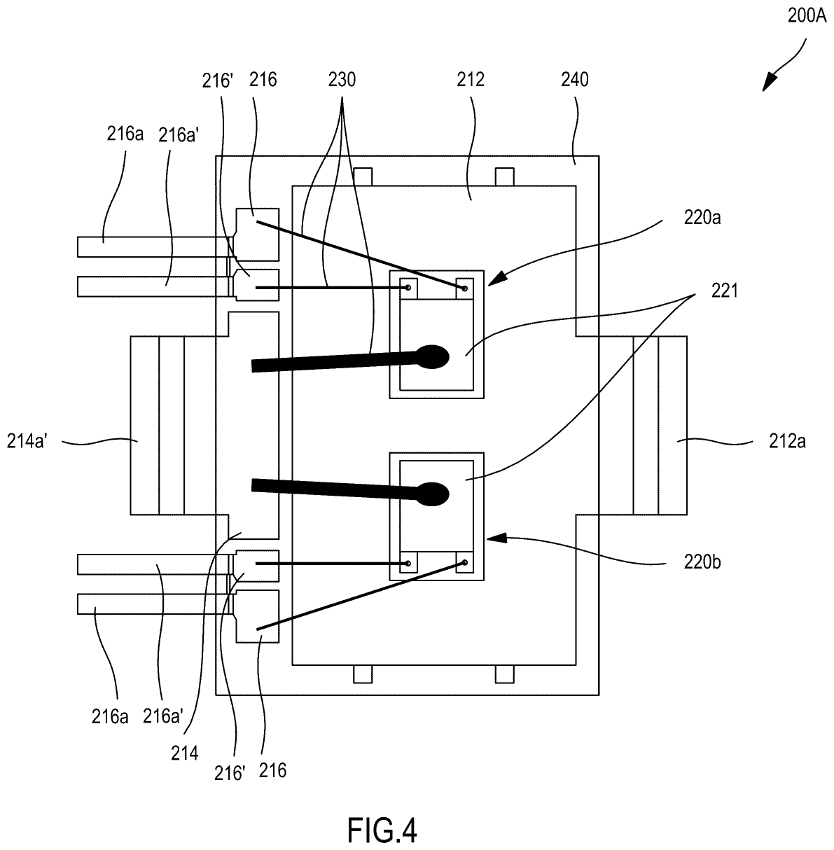

FIG. 4 shows an X-ray view of an example electronic device 200A. In the example shown in FIG. 4, electronic device 200A can be similar to electronic device 200 described above. However, external source terminal 214a′ can be provided as a single piece or single tab rather than being divided into multiple individual external leads. In some examples, one external source terminal 214a′ can extend and be bent in a downward direction from a single source contact 214. In some examples, the width of external source terminal 214a′ can be smaller than source contact 214. In some examples, the placement location of source contact 214 can be opposite to drain contact 212. In some examples, the width of source contact 214 can be similar to drain contact 212. Because the width of external source terminal 214a′ is similar to the width of external drain terminal 212a, the allowable current can be increased. Electronic device 200A is an example of a power module configured to include two or more power semiconductor devices within a small form factor and that uses a top exposed contact (e.g., a top exposed drain contact) to promote heat dissipation. Electronic device 200A is an example of a modular electronic package and a pair of electronic devices 200A can comprise or be referred to as a first modular electronic package and a second modular electronic package.

In some examples, electronic device 200 can comprise or be referred to as a top exposed pad modular power electronic package. In other examples, electronic device 200A can comprise drain contact 112 with external drain terminals 112a and 112b separated by gap 112e as well as one or more of chamfers 112c, grooves 112d, or grooves 114d as described previously with FIGS. 1A to 1F.

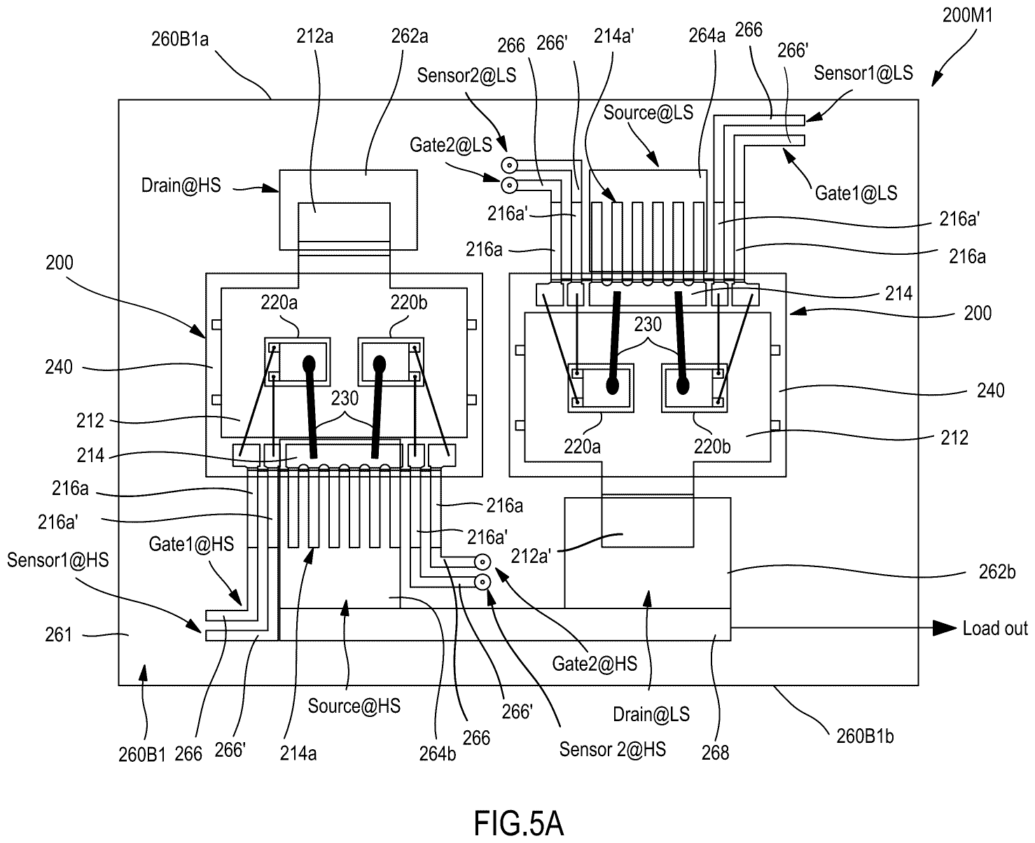

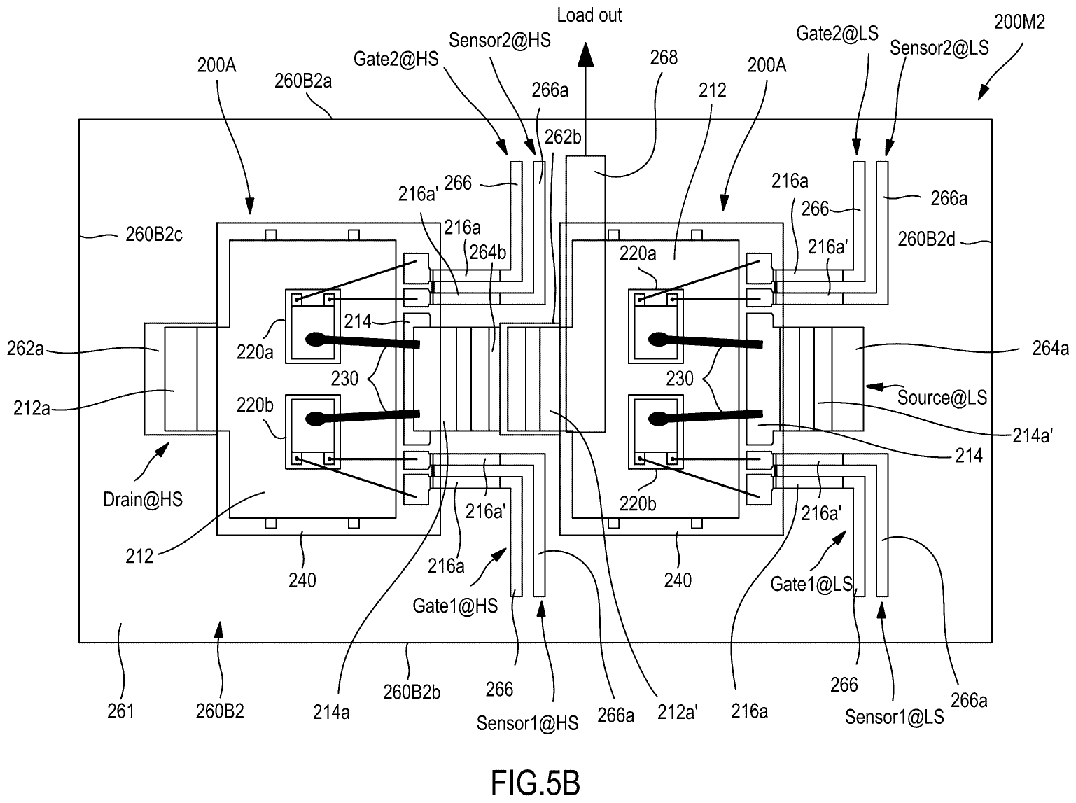

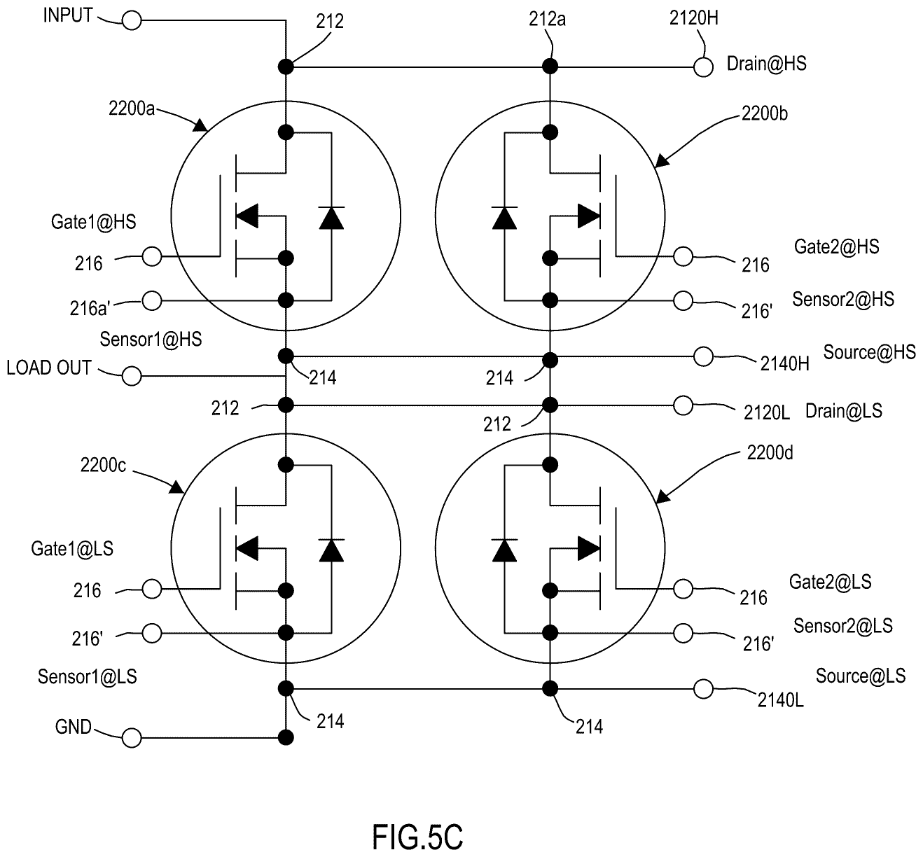

FIG. 5A shows a view of an example electronic module 200M1 with a pair of example electronic devices 200 from FIG. 3A coupled to a board 260B1, and FIG. 5B shows a view of an example electronic module 200M2 with a pair of example electronic devices 200A of FIG. 4 coupled to a top side of board 260B2. The views of FIGS. 5A and 5B are X-ray views looking up through the bottom sides of board 260B1 and board 260B2 on which electronic devices 200 and 200A are mounted, respectively. More particularly, electronic components 220a and 220b are interposed between the top sides of boards 260B1 and 260B2 and drain contacts 112. Boards 260B1 and board 260B2 can also comprise or be referred to as assembly substrate, carrier substrates, module boards, or assembly boards.

In the example shown in FIG. 5A, electronic module 200M1 can comprise a pair of electronic devices 200 coupled to board 260B1. In the example shown in FIG. 5B, electronic module 200M2 can comprise a pair of electronic devices 200A coupled to board 260B2. In some examples, board 260B1 and board 260B2 can each comprise or be referred to as a printed circuit board (PCB), a printed wiring board (PWB), a ceramic board, a next level of assembly, or a silicon board. Board 260B1 and board 260B2 can each comprise dielectric 261 and conductive patterns, which can comprise or be referred to as drain patterns 262a and 262b, source patterns 264a and 264b, and gate patterns 266, respectively. In some examples, board 260B1 and board 260B2 can comprise sensor patterns 266a, which can also comprise or be referred to as sense patterns. Drain patterns 262a and 262b are examples of a first conductive patterns, source patterns 264a and 264b are examples of second conductive patterns, gate patterns 266 are examples of third conductive patterns, and sensor patterns 266a are examples of fourth conductive patterns. Gate patterns 266 and sensor patterns 266a can be configured to electrically couple to one or more control IC's located on board 260B1 and board 260B2 or located external thereto.

In the example shown in FIG. 5A, board 260B1 can comprise drain pattern 262a and source pattern 264a provided proximate to a first side 260B1a of board 260B1 and spaced apart therefrom in a lateral direction. Board 260B1 can comprise source pattern 264b and drain pattern 262b provided proximate to a second side 260B1b and spaced apart in a lateral direction. In the present example, second side 260B1b is opposite to first side 260B1a. In some examples, source pattern 264b and drain pattern 262b proximate to second side 260B1b can be connected to each other by connection pattern 268. In some examples, a load output terminal can be connected to connection pattern 268. Board 260B1 can comprise gate patterns 266 and sensor patterns 266a provided proximate to first side 260B1a and second side 260B1b, respectively.

A pair of electronic devices 200 can be mounted on board 260B1. In some examples, the pair of electronic devices 200 can be mounted on board 260B1 in a drain contact up orientation so that drain contacts 212 of electronic devices 200 face away from and are distal or opposite to the mounting surface on board 260B1. In this way, the exposed drain contact 212 (see, for example, FIG. 3B) is positioned for enhanced heat transfer or dissipation in electronic module 200M1. In this orientation, the source regions of electronic components 220a and 220b face or are proximate to the mounting surface of board 260B1.

In some examples, on one side of board 260B1 (e.g., the left side of FIG. 5A), external drain terminal 212a of the first one of the pair of electronic devices 200 can be coupled to drain pattern 262a proximate to first side 260B1a of board 260B1 (denoted as Drain@HS or high-side drain node) and external source terminal 214a can be coupled to source pattern 264b proximate to second side 260B1b (denoted as Source@HS or high-side source node). External gate terminal 216a of the first one of the pair of electronic devices 200 can be coupled to gate pattern 266 proximate to second side 260B11b (denoted as Gate@HS or high-side gate node) and the external sensor terminal 216a′ can be coupled to the sensor pattern 266a proximate to second side 260B1b (denoted as Sensor@HS or high-side sensor node). In some examples, on the other side of board 260B1 (for example, the right side of FIG. 5A), external drain terminal 212a of the second one of the pair of electronic devices 200 can be coupled to drain pattern 262b proximate to second side 260B1b of board 260B1 (denoted as Drain@LS or low-side drain node), and external source terminal 214a can be coupled to source pattern 264a proximate to first side 260B1a (denoted as Source@LS or low-side source node). External gate terminal 216a of the second one of the pair of electronic devices 200 can be coupled to gate pattern 266 proximate to first side 260B1a (denoted as Gate@LS or low-side gate node), and external sensor terminal 216a′ can be coupled to the sensor pattern 266a proximate to first side 260B1a (denoted as Sensor@LS or low-side sensor node).

In the present example, electronic devices 200 are oriented in different directions on board 261B1. In some examples, electronic devices 200 are oriented or rotated 180 degrees with respect to each other. In some examples, electronic module 200M1 is configured as a half-bridge single phase for a DC/DC converter. In accordance with the present description, because electronic devices 200 each include two or more power electronic components in a single package, a modular power package configuration is provided within a small footprint or form factor. In addition, top exposed drain contacts 212 (see for example, FIG. 3B) provide improved heat dissipation. The left one of electronic devices 200 in FIG. 5A is an example of a first modular electronic package comprising a high-side switching device and the right one of electronic device 200 in FIG. 5A is an example, of a second modular electronic package comprising a low-side switching device.

It is understood that electronic devices 200 in electronic module 200M1 can use any of the features described in FIGS. 1A to 1F for the drain terminals and the source terminals including drain contacts 112 with projections 1121a and 1121 b and extensions 1122a and 1122b, gaps 112e, chamfers 112c, grooves 112d, or grooves 114d.

In the example shown in FIG. 5B, board 260B2 can comprise drain pattern 262a provided proximate a third side 260B2c of board 260B2 and source pattern 264a provided proximate to a fourth side 260B2d and spaced apart from each other in a lateral direction. Board 260B2 can comprise drain pattern 262b and source pattern 264b provided in a central portion of board 260B2. In some examples, source pattern 264b and drain pattern 262b can be coupled using connection pattern 268. In some examples, a load output terminal can be connected to connection pattern 268. Board 260B2 can comprise gate patterns 266 and sensor patterns 266a spaced apart from each proximate to first side 260B2a of board 260B2 and proximate to second side 260B2b respectively.

A pair of electronic devices 200A can be mounted on board 260B2. In some examples, the pair of electronic devices 200A can be mounted on board 260B2 in a drain contact up orientation so that drain contacts 212 of electronic devices 200A face away from and are distal to or opposite to the mounting surface on board 260B2. In this way, the exposed drain contact 212 (see, for example, FIG. 3B) is positioned for enhanced heat transfer or dissipation in electronic module 200M2. In this orientation, the source regions of electronic components 220a and 220b face or are proximate to the mounting surface of board 260B2.

In some examples, on one side of board 260B2 (e.g., the left side of FIG. 5B), external drain terminal 212a of the first one of the pair of electronic devices 200A can be coupled to drain pattern 262a proximate third side 260B2c of board 260B2 (denoted as Drain@HS or high-side drain node) and external source terminal 214a of the second one of the pair of electronic devices 200A can be coupled to source pattern 264a proximate to fourth side 260B2d (denoted as Source@LS or low-side source node). External gate terminal 216a of the first one of the pair of electronic devices 200A can be coupled to gate pattern 266 proximate to second side 260B2b (denoted as Gate@HS or high-side gate node) and external sensor terminals 216a′ can be coupled to the sensor pattern 266a proximate to second side 260B2b (denoted as Sensor@HS or high-side sensor node) and sensor pattern 266a proximate to first side of 260B2a. In some examples, on the other side of board 260B2 (for example, the right side of FIG. 5B), external gate terminals 216a of the second one of the pair of electronic devices 200A can be coupled to gate pattern 266 proximate to second side 260B2b (denoted as Gate@LS or low-side gate node) and to gate pattern 266 proximate to first side 260B2a, and external sensor terminals 216a′ can be coupled to sensor pattern 266a proximate to second side 260B2b (denoted as Sensor@LS or low-side sensor node) and to sensor pattern 266a proximate to first side 260B2a.

In the present example, electronic devices 200A are oriented in different directions on board 261B2. In some examples, electronic devices 200A are oriented or mounted on board 260B2 in a mirrored-image arrangement. In some examples, electronic module 200M2 is configured as a half-bridge single phase for a DC/DC converter. In accordance with the present description, because electronic devices 200A each include two or more power electronic components in a single package, a modular power package configuration is provided within a small footprint or form factor. In addition, top exposed drain contacts 212 (see for example, FIG. 3B) provide improved heat dissipation. The left one of electronic devices 200A in FIG. 5B is an example of a first modular electronic package comprising a high-side switching device and the right one of electronic device 200A in FIG. 5B is an example, of a second modular electronic package comprising a low-side switching device.

It is understood that electronic devices 200A in electronic module 200M2 can use any of the features described in FIGS. 1A to 1F for the drain terminals and the source terminals including drain contacts 112 with projections 1121a and 1121b and extensions 1122a and 1122b, gaps 112e, chamfers 112c, grooves 112d, or grooves 114d.

FIG. 5C shows an equivalent circuit diagram of a switching circuit for electronic modules 200M1 and 200M2 of FIGS. 5A and 5B. In the present example, the switching circuit. can comprise first, second, third, and fourth (N-Channel) MOSFETS, 2200a, 2200b, 2200c, and 2200d respectively connected in parallel and in series with each other. In other examples, the switching circuit can comprise P-Channel MOSFET or IGBTs connected in parallel and in series with each other. In some examples, first MOSFET 2200a and second MOSFET 2200b can be co-packaged in one of electronic devices 200 in FIG. 5A (for example, the left one) or in one of electronic devices 200A in FIG. 5B (for example, the left one), and third MOSFET 2200c and fourth MOSFET 2200c can be co-packaged in the one of the electronic devices 200 in FIG. 5A (for example, the right one) or in the other one of electronic device 200A in FIG. 5B (for example, the right one).

In some examples, first MOSFET 2200a and second MOSFET 2200b can be arranged on the upper side of switching circuit and can comprise or be referred to as high-side switches, and third MOSFET 2200c and fourth MOSFET 2200d can be arranged on the lower side of the switching circuit and can comprise or be referred to as low-side switches.

In some examples, the drain region of first electronic component 220a and the drain region of second electronic component 220b in the left one of electronic devices 200 in FIG. 5A and in the left one of electronic devices 200A in FIG. 5B are coupled to drain contact 212. In the t switching circuit of FIG. 5C, the drain region (denoted as drain contact 212) of first MOSFET 2200a and the drain region (denoted as drain contact 212) of second MOSFET 2200b can be coupled through external drain terminal 212a and drain pattern 262a (see FIGS. 5A and 5B) to provide drain node 2120H, which can also comprise or be referred to as the high-side drain node or Drain@HS node. In the present example, drain regions of first MOSFET 2200a and second MOSFET 2200b can be coupled to an INPUT node through drain contact 212 in the switching circuit of FIG. 5C.

In some examples, the source region of first electronic component 220a and the source region of second electronic component 220b in the left one of electronic devices 200 in FIG. 5A and the left one of electronic devices 200A in FIG. 5B are coupled to a common source contact 214 (see, for example, FIG. 4). In the equivalent switching circuit of FIG. 5C, the source region (denoted as source contact 214) of first MOSFET 2200a and the source region (denoted as source contact 214) of second MOSFET 2200b are coupled through external source terminal(s) 214a and source pattern 264b (see FIGS. 5A and 5B) to provide source node 2140H, which can also comprise or be referred to as a high-side source node or Source@HS node.

In some examples, the drain region of the first electronic component 220a and the drain region of second electronic component 220b in the right one of electronic devices 200 in FIG. 5A and the drain region of first electronic component 220a and the drain region of the of the second electronic component 220b in the right one of electronic devices 200A in FIG. 5B are coupled to drain contact 212. In the switching circuit of FIG. 5C, the drain region (denoted as drain contact 212) of third MOSFET 2200c and drain region (denoted as drain contact 212) of the fourth MOSFET 2200d can be coupled through external drain terminal 212a′ and drain pattern 262b (see FIGS. 5A and 5B) to provide drain node 2120L, which can also be comprise or be referred to as the low-side drain node or Drain@LS node. In the present example, drain node 2120L is coupled to source node 2140H to provide a LOAD OUT node in the switching circuit of FIG. 5C.

In some examples, the source region of first electronic component 220a and the source region of the second electronic component 220b in the right one of electronic devices 200 in FIG. 5A and the source region of the first electronic component 220a and the source region of the second electronic component 220b in the right one of electronic devices 200A in FIG. 5B are coupled to a common source contact 214. In the switching circuit of FIG. 5C, the source region (denoted as source contact 214) in third MOSFET 2200c and the source region (denoted as source contact 214) in fourth MOSFET 2200d can be coupled through external source terminal(s) 214a′ and source pattern 264a (see FIGS. 5A and 5B) to provide source node 2140L, which can also comprise or be referred to as the low-side source node or Source@LS node. In the present example, source node 2140L can be coupled to a GND node in the switching circuit of FIG. 5C.

In some examples, the gate region of first electronic component 220a and the gate region of second electronic component 220b of the left one of electronic devices 200 in FIG. 5A and the gate region of the first electronic component 220a and the gate region of the second electronic component 220b in the left one of the electronic devices 200A in FIG. 5B are each coupled to separate gate contacts 216 and separate external gate terminals 216a (see FIG. 4). In the switching circuit of FIG. 5C, the gate region (denoted as gate contact 216) of first MOSFET 2200a and the gate region (denoted as gate contact 216) of second MOSFET 2200b are separated from each other and can be separately biased or commonly biased at a board level using, for example, a control IC. In the present example, gate contact 216 of first MOSFET 2200a can be coupled to external gate terminal 216a and gate pattern 266 (see FIG. 5A and FIG. 5B) to provide the first high-side gate node or Gate1 @HS node, and gate contact 216 of second MOSFET 2200b can be coupled to another external gate terminal 216a and another gate pattern 266 (see FIG. 5A and FIG. 5B) to provide the second high-side gate node or a Gate2@HS node.

In some examples, the gate region of first electronic component 220a and the gate region of second electronic component 220b of the right one of electronic devices 200 in FIG. 5A and the gate region of the first electronic component 220a and the gate region of the second electronic component 220b in the right one of the electronic devices 200A in FIG. 5B are coupled to separate gate contacts 216 (see FIG. 4) and separate external gate terminals 216a. In the switching circuit of FIG. 5C, the gate (denoted as gate contact 216) of third MOSFET 2200c and the gate region (denoted as external gate contact 216) of fourth MOSFET 2200d are separated from each other and can be separately biased or commonly biased at a board level using, for example, a control IC. In the present example, gate contact 216 of third MOSFET 2200c can be coupled to external gate terminal 216a and gate pattern 266 (see FIG. 5A and FIG. 5B) to provide the first low-side gate node or Gate1 @LS node, and gate contact 216 of fourth MOSFET 2200b can be coupled to another external gate terminal 216a and another gate pattern 266 (see FIG. 5A and FIG. 5B) to provide the second low-side gate node or Gate2@LS node.

In some examples, the sensor region of first electronic component 220a and the sensor region of second electronic component 220b of the left one of the electronic devices 200 in FIG. 5A and the left one of the electronic devices 200A in FIG. 5B are each coupled to separate sensor contacts 216′ (see FIG. 4) and separate external sensor terminals 216a′. In the switching circuit of FIG. 5C, the sensor region (denoted as sensor contact 216′) of first MOSFET 2200a and the sensor region (denoted as sensor contact 216′) of second MOSFET 2200b are separated from each other and can be separately monitored or commonly monitored at a board level by using, for example, a control IC. In the present example, sensor contact 216′ of first MOSFET 2200a can be coupled to an external sensor terminal 216a′ and sensor pattern 266a (see FIG. 5A and FIG. 5B) to provide the first high-side sensor node or a Sensor1@HS node, and sensor contact 216′ of second MOSFET 2200b can be coupled to another external sensor terminal 216a′ and another sensor pattern 266a (see FIG. 5A and FIG. 5B) to provide the second high-side sensor node or Sensor2@HS node.

In some examples, the sensor region of first electronic component 220a and the sensor region of second electronic component 220b of the right one of the electronic devices 200 in FIG. 5A and the right one of the electronic devices 200A in FIG. 5B are each coupled to separate sensor contacts 216′ (see FIG. 4) and separate external sensor terminals 216a′. In the switching circuit of FIG. 5C, the sensor region (denoted as sensor contact 216′) of third MOSFET 2200c and the sensor region (denoted as sensor contact 216′) of fourth MOSFET 2200d are separated from each other and can be separately monitored or commonly monitored at a board level using, for example, control IC. In the present example, sensor contact 216′ of third MOSFET 2200a can be coupled through an external sensor terminal 216a′ and sensor pattern 266a (see FIG. 5A and FIG. 5B) to provide the first low-side sensor node or a Sensor1@LS node, and sensor contact 216′ of fourth MOSFET 2200b can be coupled through another external sensor terminal 216a′ and sensor pattern 166a (see FIG. 5A and FIG. 5B) to provide the second low-side sensor node or Sensor2@LS node.

In some examples, the switching circuit shown in FIG. 5C using electronic modules 200M1 or electronic modules 200M2 can be used as a component of a DC-DC converter. In some examples, the above-described switching circuit can be adopted in a single-phase half-bridge converter converting a high voltage DC to an AC voltage through high-side and low-side switching elements, converts the AC voltage in a transformation ratio of a transformer, and then converts the same back to a DC voltage through a rectifier.

In summary, structures and associated methods that relate to power modules configured to include two or more power semiconductor devices within a small form factor assembly and that use a top exposed contact to promote heat dissipation have been described. In some examples, the top exposed contact can be used as a first current carrying terminal for the power module, such as a drain contact, and can be provided with a first external terminal and a second external terminal extending from a side of the contact for connecting to a next level of assembly. In some examples, the first external terminal can extend in a first direction and the second external terminal can extend in a second direction different than the first direction. In some examples, the first external terminal and the second external terminal can be laterally separated by gap or void configured to reduce height deviation between the first external terminal and the second external terminal.

In some examples, a chamfered cutout can be provided in the contact between the first and second external terminals to reduce twisting and stress when manufacturing the power module. In some examples, grooves can be provided in edges of the first and second external terminals proximate to the contact to improve adhesion between the contact and the package encapsulant. In some examples, the power module comprises second current carrying terminals, such as source terminals, which can be provided with partially coined portions configured to improve adhesion between the source terminals and the package encapsulant.

The modular electronic packages described herein can be used in a variety of power conversion implementations including DC/DC half-bridges for single phase applications based on their design flexibility.

The present disclosure includes reference to certain examples; however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure is not limited to the examples disclosed, but that the disclosure will include all examples falling within the scope of the appended claims.

What is claimed is:

1. An electronic device, comprising:
a substrate comprising:
a first contact comprising a first contact top side, a first contact bottom side opposite to the first contact top side, a first contact first lateral side, and a first contact second lateral side opposite to the first contact first lateral side;
a first contact first external terminal coupled to and extending outward from the first contact first lateral side;
a first contact second external terminal coupled to and extending outward from the first contact first lateral side, wherein the first contact second external terminal and the first contact first external terminal are separated by a gap;
a second contact proximate to and laterally separated from the first contact second lateral side;
a second contact first external terminal coupled to and extending outward from the second contact;
a second contact second external terminal coupled to and extending outward from the second contact;
a third contact proximate to and laterally separated from the first contact second lateral side; and
a third contact first external terminal coupled to and extending outward from the third contact;
a first electronic component comprising a first electronic component top side and a first electronic component bottom side opposite to the first electronic component top side, wherein the first electronic component bottom side is coupled to the first contact top side, a first part of the first electronic component top side is electrically coupled to the second contact, and a second part of the first electronic component is electrically coupled to the third contact; and
an encapsulant covering the substrate and the first electronic component;
wherein:
the encapsulant comprises an encapsulant top side, an encapsulant bottom side opposite to the encapsulant top side, and an encapsulant lateral side;
the first contact first external terminal, the first contact second external terminal, the second contact first external terminal, the second contact second external terminal, and the third contact first external terminal are exposed from the encapsulant;
the first contact bottom side is exposed from the encapsulant top side; and
the encapsulant covers a portion of the gap proximate to the first contact first lateral side.

2. The electronic device of claim 1, wherein:
the first contact first external terminal comprises:
a first projection extending outward from the first contact first lateral side; and
a first extension extending outward from the first projection in a first direction; and
the first contact second external terminal comprises:
a second projection extending outward from the first contact first lateral side and separated from the first projection by the gap; and
a second extension extending outward from the second projection in a second direction different than the first direction.

3. The electronic device of claim 2, wherein:
the first extension extends from the first projection in a direction towards the encapsulant bottom side; and
the second extension extends from the second projection in the direction towards the encapsulant bottom side.

4. The electronic device of claim 2, further comprising:
chamfers in the first contact first lateral side, a lateral side of the first projection and a lateral side of the second projection, wherein the encapsulant covers the chamfers.

5. The electronic device of claim 2, further comprising:
grooves that extend partially into surfaces of the first projection and the second projection, wherein the encapsulant covers the grooves.

6. The electronic device of claim 2, wherein the first direction is opposite the second direction.

7. The electronic device of claim 1, wherein:
the first contact resides on a first plane;
the second contact and the third contact reside on a second plane; and
the first plane is elevated above the second plane in a cross-sectional view.

8. The electronic device of claim 1, further comprising:
a groove that extends partially into the second contact between the second contact first external terminal and the second contact second external terminal, wherein the encapsulant covers the groove.

9. The electronic device of claim 1, wherein:
the second contact first external terminal and the second contact second external terminal extend from the second contact a direction towards the encapsulant bottom side; and
the third contact first external terminal extends from the third contact in the direction towards the encapsulant bottom side.

10. The electronic device of claim 1, further comprising:
a fourth contact; and
a fourth contact first external terminal coupled to and extending outward from the fourth contact;
wherein:
a third part of the first electronic component top side is electrically coupled to the fourth contact; and
the fourth contact first external terminal is exposed from the encapsulant.

11. An electronic device, comprising:
a first modular electronic package comprising:
a first substrate comprising:
a first current carrying contact comprising a first side, a second side opposite to the first side, a first lateral side, and a second lateral side opposite to the first lateral side;
a first external terminal coupled to and extending from the first current carrying contact;
a second current carrying contact;
a second external terminal coupled to and extending from the second current carrying contact;
a first control contact;
a first control contact external terminal coupled to and extending from the first control contact;
a second control contact; and
second control contact external terminal coupled to and extending from the second control contact;
a first electronic component comprising a first electronic component top side, a first electronic component bottom side opposite to the first electronic component bottom side, wherein the first electronic component bottom side is coupled to the first side of the first current carrying contact, a first part of the first electronic component top side is coupled to the second current carrying contact, and a second part of the first electronic component top side is coupled to the first control contact;
a second electronic component comprising a second electronic component top side and a second electronic component bottom side opposite to the second electronic component top side, wherein the second electronic component bottom side is coupled to the first side of the first current carrying contact, a first part of the second electronic component top side is coupled to the second current carrying contact, and a second part of the second electronic component top side is coupled to the second control contact; and
a first encapsulant covering the first substrate, the first electronic component, and the second electronic component;
wherein:
the first encapsulant comprises a first encapsulant top side, a first encapsulant bottom side opposite to the first encapsulant top side, a first encapsulant first lateral side, and a first encapsulant second lateral side opposite to the first encapsulant first lateral side;
the second side of the first current carrying contact is exposed from the first encapsulant top side;
the first external terminal is exposed from the first encapsulant at the first encapsulant first lateral side; and
the second external terminal, the first control contact external terminal, and the second control contact external terminal are exposed from the first encapsulant at the first encapsulant second lateral side.

12. The electronic device of claim 11, wherein:
the first external terminal extends from the first current carrying contact toward the first encapsulant bottom side; and
the second external terminal extends from the second current carrying contact in a direction toward the first encapsulant bottom side.

13. The electronic device of claim 11, wherein the first external terminal comprises:
a first projection extending outward from the first current carrying contact;
a first extension extending outward from the first projection in a first direction;
a second projection extending outward from the first current carrying contact separated from the first projection by a gap; and
a second extension extending outward from the second projection in a second direction different than the first direction;
wherein:
the first extension extends from the first projection in a direction towards the first encapsulant bottom side; and
the second extension extends from the second projection in the direction towards the first encapsulant bottom side.

14. The electronic device of claim 13, further comprising:
chamfers in the first lateral side, a lateral side of the first projection and a lateral side of the second projection; and
grooves that extend partially into surfaces of the first projection and the second projection;
wherein:
the first encapsulant covers the chamfers and the grooves.

15. The electronic device of claim 11, further comprising:
grooves extending partially into the second current carrying contact;
wherein:
the second external terminal is one of a plurality of second external terminals coupled to and extending from the second current carrying contact;
the grooves are interposed between adjacent ones of the plurality of second external terminals; and
the first encapsulant covers the grooves.

16. The electronic device of claim 11, further comprising:
an assembly board comprising a top side; and
a second modular electronic package comprising:
a second substrate comprising:
a first current carrying contact comprising a first side, a second side opposite to the first side, a first lateral side, and a second lateral side opposite to the first lateral side;
a first external terminal coupled to and extending from the first current carrying contact;
a second current carrying contact;
a second external terminal coupled to and extending from the second current carrying contact;
a first control contact;
a first control contact external terminal coupled to and extending from the first control contact;
a second control contact; and
second control contact external terminal coupled to and extending from the second control contact;
a third electronic component comprising a third electronic component top side, a third electronic component bottom side opposite to the third electronic component bottom side, wherein the third electronic component bottom side is coupled to the first side of first current carrying contact of the second substrate, a first part of the third electronic component top side is coupled to the second current carrying contact of the second substrate, and a second part of the third electronic component top side is coupled to the first control contact of the second substrate;
a fourth electronic component comprising a fourth electronic component top side and a fourth electronic component bottom side opposite to the fourth electronic component top side, wherein the fourth electronic component bottom side is coupled to the first side of the first current carrying contact of the second substrate, a first part of the fourth electronic component top side is coupled to the second current carrying contact of the second substrate, and a second part of the second electronic component top side is coupled to the second control contact of the second substrate; and
a second encapsulant covering the second substrate, the third electronic component, and the fourth electronic component;
wherein:
the second encapsulant comprises a second encapsulant top side, a second encapsulant bottom side opposite to the second encapsulant top side, a second encapsulant first lateral side, and a second encapsulant second lateral side opposite to the second encapsulant first lateral side;
the first current carrying contact second side of the second substrate is exposed from the second encapsulant top side;
the first external terminal of the second substrate is exposed from the second encapsulant at the second encapsulant first lateral side;
the second external terminal, the first control contact external terminal, and the second control contact external terminal of the second substrate are exposed from the second encapsulant at the second encapsulant second lateral side;
the first modular electronic package is coupled to the top side of the assembly board so that the first current carrying contact of the first substrate is distal to and faces away from the top side of the assembly board;
the second modular electronic package is coupled to the top side of the assembly board so that the first current carrying contact of the second substrate is distal to and faces away from the top side of the assembly board; and
the second current carrying contact of the first modular electronic package is coupled to the first current carrying contact of the second modular electronic package.

17. The electronic device of claim 16, wherein:
the first modular electronic package comprises a high-side switching device;
the second modular electronic package comprises a low-side switching device; and
the first modular electronic package and the second modular electronic package are oriented in different directions on the assembly board.

18. The electronic device of claim 17, wherein:
the first modular electronic package and the second modular electronic package are oriented so that the second external terminal of the first modular electronic package and the second external terminal of the second modular electronic package are oriented in opposite directions.

19. A method of manufacturing an electronic device, comprising:
providing a substrate comprising:
a first contact comprising a first contact top side, a first contact bottom side opposite to the first contact top side, a first contact first lateral side, and a first contact second lateral side opposite to the first contact first lateral side;
a first contact first external terminal coupled to and extending outward from the first contact first lateral side;
a first contact second external terminal coupled to and extending outward from the first contact first lateral side, wherein the first contact second external terminal and the first contact first external terminal are separated by a gap;
a second contact proximate to and laterally separated from the first contact second lateral side;
a second contact first external terminal coupled to and extending outward from the second contact;
a second contact second external terminal coupled to and extending outward from the second contact;
a third contact proximate to and laterally separated from the first contact second lateral side; and
a third contact first external terminal coupled to and extending outward from the third contact;
providing a first electronic component comprising a first electronic component top side and a first electronic component bottom side opposite to the first electronic component top side, wherein the first electronic component bottom side is coupled to the first contact top side, a first part of the first electronic component top side is electrically coupled to the second contact, and a second part of the first electronic component is electrically coupled to the third contact; and
providing an encapsulant covering the substrate and the first electronic component;
wherein:
the encapsulant comprises an encapsulant top side, an encapsulant bottom side opposite to the encapsulant top side, and an encapsulant lateral side;
the first contact first external terminal, the first contact second external terminal, the second contact first external terminal, the second contact second external terminal, and the third contact first external terminal are exposed from the encapsulant;
the first contact bottom side is exposed from the encapsulant top side; and
the encapsulant covers a portion of the gap proximate to the first contact first lateral side.

20. The method of claim 19, wherein:
providing the substrate comprises:
providing chamfers in the substrate;
providing the first contact first external terminal comprising:
a first projection extending outward from the first contact first lateral side; and
a first extension extending outward from the first projection in a first direction; and
providing the first contact second external terminal comprising:
a second projection extending outward from the first contact first lateral side and separated from the first projection by the gap; and
a second extension extending outward from the second projection in a second direction different than the first direction;
the first extension extends from the first projection in a direction towards the encapsulant bottom side;
the second extension extends from the second projection in the direction towards the encapsulant bottom side;
the chamfers are provided in the first contact first lateral side, a lateral side of the first projection and a lateral side of the second projection; and
providing the encapsulant comprises providing the encapsulant covering the chamfers.
